(19) United States
(12) Patent Application Publication
(10) Pub. No.: US 2011/0146910 A1
(43) Pub. Date: Jun. 23, 2011

(54) PLASMA PROCESSING APPARATUS

(75) Inventors: Masaki Hirayama, Miyagi (JP); Tadahiro Ohmi, Miyagi (JP)

(73) Assignees: TOKYO ELECTRON LIMITED, Tokyo (JP); TOHOKU UNIVERSITY, Sendai-shi (JP)

(21) Appl. No.: 12/997,122

(22) PCT Filed: Jun. 5, 2009
(86) PCT No.: PCT/JP2009/060345

§ 371 Date: Mar. 14, 2011

(30) Foreign Application Priority Data
Jun. 11, 2008 (JP) 2008-153324

(51) Int. Cl. C23F 1/08; C23C 16/50

(52) U.S. Cl. 156/345.43; 118/723 E

(57) ABSTRACT

Uniformity of a process on a substrate is improved. A plasma processing apparatus including a processing container which is formed of metal and receives a substrate to be plasma-processed, an electromagnetic wave source which supplies an electromagnetic wave required to excite plasma in the processing container, and a plurality of dielectrics, through which the electromagnetic wave supplied from the electromagnetic wave source transmits to the inside of the processing container and which have a part that is exposed to the inside of the processing container, on a lower surface of a lid of the processing container, wherein a metal electrode, which is electrically connected to the lid, is formed on a lower surface of each dielectric, a part of each dielectric exposed between the lower surface of the lid and the metal electrode has a substantially polygonal outline when viewed from the inside of the processing container, the plurality of dielectrics are disposed with vertical angles of the polygonal outlines being adjacent to each other, and a surface wave propagating portion, through which the electromagnetic wave is propagated, is formed on the lower surface of the lid exposed inside the processing container and a lower surface of the metal electrode.

### TECHNICAL FIELD

The present invention relates to a plasma processing apparatus for performing a process, such as a film-forming or the like, on a substrate by exciting plasma.

### BACKGROUND ART

A plasma processing apparatus for performing a CVD process, an etching process, or the like on a substrate by exciting plasma in a processing container by using a microwave is used in a process of manufacturing, for example, a semiconductor device, an LCD device, or the like. As such a plasma processing apparatus, an apparatus, which supplies a microwave from a microwave source through a coaxial waveguide or a waveguide to a dielectric disposed on an inner surface of the processing container, and plasmatizes a predetermined gas supplied into the processing container by using energy of the microwave, is known.

Recently, a size of the plasma processing apparatus increases with an increasing size of a substrate, but when the dielectric disposed on the inner surface of the processing container is a single plate, it is difficult to prepare the dielectric having a large size, and thus manufacturing costs may be highly increased. Accordingly, in order to settle such inconvenience, the applicants previously suggested a technology of dividing a dielectric plate into a plurality of numbers by attaching a plurality of dielectrics on a lower surface of a lid of the processing container (Patent Document 1).

[Patent Document 1] Japanese Laid-Open Patent Publication No. 2006-310794

### DISCLOSURE OF THE INVENTION

### Technical Problem

However, such a conventional plasma processing apparatus using a microwave has a configuration where a microwave of, for example, 2.45 GHz output from a microwave source penetrates through a dielectric disposed on a lower surface of a lid of a processing container and is supplied into the processing container. Here, the dielectric is disposed to cover almost all of a processing surface (upper surface) of a substrate received in the processing container, and an area of an exposed surface of the dielectric exposed inside the processing container was almost the same as an area of the processing surface of the substrate. Accordingly, a uniform process was performed on the entire processing surface of the substrate by using plasma generated on the entire lower surface of the dielectric.

However, as in the conventional plasma processing apparatus, when the area of the exposed part of the dielectric is almost the same as the area of the processing surface of the substrate, a used amount of the dielectric is increased, and it costs much. Specifically recently, the size of the substrate is being increased, and thus the used amount of the dielectric is increased more, thereby increasing expenses.

Also, when the dielectric is disposed on the entire lower surface of the lid of the processing container, it is difficult to uniformly supply a processing gas to the entire processing surface of the substrate. In other words, for example, Al₂O₃ or the like is used as the dielectric, but it is difficult to manufacture a gas supply hole in the dielectric compared to manufacturing a gas supply hole in the lid formed of a metal, and generally, the gas supply hole is formed only in an exposed place of the lid. Accordingly, it becomes difficult to uniformly supply a processing gas in a state like in a shower plate on the entire processing surface of the substrate.

In a plasma process, such as an etching, CVD (chemical vapor deposition), or the like, a self bias voltage (negative direct voltage) may be generated on the substrate by applying a high frequency bias on the substrate, so as to control energy of ions incident on a surface of the substrate from plasma. Here, it is preferable that the high frequency bias applied to the substrate is applied only to a sheath around the substrate, but, if a ground surface (the inner surface of the processing container) is difficult to be seen from the plasma since most of the inner surface of the processing container is covered by the dielectric, the high frequency bias may also be applied to a sheath around the ground surface. Accordingly, it is not only required to apply excessively large high frequency power to the substrate, but the ground surface is etched since the energy of ions incident on the ground surface is increased, and thus metal contamination may be generated.

Also, when a microwave of high power is transmitted so as to increase a processing rate, a temperature of the dielectric is increased due to incidence of ions or electrons from the plasma, thereby damaging the dielectric by a thermal stress, or generating impurity contamination as an etching reaction on the surface of the dielectric is accelerated.

### Technical Solution

As described above, in the plasma processing apparatus using the microwave, the microwave source outputting the microwave of 2.45 GHz is generally used based on reasons, such as easiness in obtainment, economic feasibility, etc. Meanwhile, recently, a plasma process using a microwave having a low frequency of 2 GHz or lower is being suggested, and a plasma process using a microwave having a relatively low frequency of, for example, 896 MHz, 915 MHz, or 922 MHz is being studied. The reason is as follows. Since a lowest limit of electron density for obtaining stable plasma having a low electron temperature is proportional to a square of a frequency, plasma suitable for a plasma process is obtained in wider conditions when the frequency is decreased.

The inventors variously studied about such a plasma process using the microwave having a low frequency of 2 GHz or lower. As a result, a new knowledge that when the microwave having a frequency of 2 GHz or lower is transmitted to the dielectric of the inner surface of the processing container, the microwave can be effectively propagated along a metal surface of the inner surface of the processing container, or the like, from the vicinity of the dielectric, and the plasma can be excited in the processing container by using the microwave that is propagated along the metal surface was obtained. Also, such a microwave that is propagated along the metal surface, between the metal surface and the plasma will be referred to as a “conductor surface wave” herein.

Meanwhile, when such a conductor surface wave is propagated along the metal surface and the plasma is excited in the processing container, if a shape or a size of a surface wave propagating portion that propagates the microwave in the vicinity of the dielectric is not uniform, the plasma excited in the processing container by the conductor surface wave also becomes non-uniform. As a result, a uniform process may not be performed on the entire processing surface of the substrate.

To solve the above and/or other problems, the present invention provides a plasma processing apparatus that excites plasma in a processing container by using a conductor surface wave, wherein uniformity of a process with respect to a substrate is improved.

According to an embodiment of the present invention, there is provided a plasma processing apparatus including a processing container which is formed of metal and receives a substrate to be plasma-processed, an electromagnetic wave source which supplies an electromagnetic wave required to excite plasma in the processing container, and a plurality of dielectrics, through which the electromagnetic wave supplied from the electromagnetic wave source transmits to the inside of the processing container and which have a part that is exposed to the inside of the processing container, provided on a lower surface of a lid of the processing container, wherein a metal electrode is provided on a lower surface of the dielectrics, and wherein a surface wave propagating portion, through which the electromagnetic wave is propagated, is formed on each of two different sides of such part of each dielectric that is exposed between the metal electrode and the lower surface of the lid, and the surface wave propagating portions on said two different sides have the substantially similar shapes as each other or the substantially symmetrical shapes to each other.

According to another embodiment of the present invention, there is provided a plasma processing apparatus including a processing container which is formed of metal and receives a substrate to be plasma-processed, an electromagnetic wave source which supplies an electromagnetic wave required to excite plasma in the processing container, and a plurality of dielectrics, through which the electromagnetic wave supplied from the electromagnetic wave source transmits to the inside of the processing container and which have a part that is exposed to the inside of the processing container, provided on a lower surface of a lid of the processing container, wherein a metal electrode is provided on a lower surface of the dielectrics, and wherein a surface wave propagating portion, through which the electromagnetic wave is propagated, is formed adjacent to at least a portion of such part of each dielectrics that is exposed between the metal electrode and the lower surface of the lid, and said adjacent surface wave propagating portion has a substantially similar shape as a shape of the dielectric, or substantially symmetrical shape to the shape of the dielectric.

According to another embodiment of the present invention, there is provided a plasma processing apparatus including a processing container which is formed of metal and receives a substrate to be plasma-processed, an electromagnetic wave source which supplies an electromagnetic wave required to excite plasma in the processing container, and a plurality of dielectrics, through which the electromagnetic wave supplied from the electromagnetic wave source transmits to the inside of the processing container and which have a part that is exposed to the inside of the processing container, provided on a lower surface of a lid of the processing container, wherein a metal electrode is provided on a lower surface of each of the dielectrics, and such part of each dielectric that is exposed between the metal electrode and the lower surface of the lid has a substantially polygonal outline when viewed from the inside of the processing container, and wherein the plurality of dielectrics are disposed with vertical angles of the polygonal outlines being adjacent to each other, and a surface wave propagating portion, through which the electromagnetic wave is propagated, is formed on the lower surface of the lid exposed in the processing container and a lower surface of the metal electrode.

In the plasma processing apparatus, the plasma may be excited in the processing container by a microwave (conductor surface wave) propagated along the surface wave propagating portion from the dielectrics. Also, according to the plasma processing apparatus, the shape or the size of the surface wave propagating portion formed around the dielectrics is almost uniform, and the plasma excited in the processing container by the conductor surface wave is uniform. As a result, a uniform process is performed on an entire processing surface of the substrate.

In the plasma processing apparatus, the dielectrics may have, for example, substantially tetragonal plate shapes. Here, the tetragon may be, for example, a square, a rhomb, a square having round corners, or a rhomb having round corners. Alternatively, the dielectrics may have, for example, substantially triangular plate shapes. Here, the triangle may be, for example, an equilateral triangle, or an equilateral triangle having round corners. A shape of the lower surface of the lid, which is surrounded by the plurality of dielectrics and exposed inside the processing container, and a shape of a lower surface of the metal electrode may be substantially identical, when viewed from the inside of the processing container.

An outer edge of each dielectric may be on an outer side than an outer edge of the metal electrode, when viewed from the inside of the processing container. Alternatively, an outer edge of each dielectric may be on a same line or on an inner side than an outer edge of the metal electrode, when viewed from the inside of the processing container.

A thickness of each dielectric may be, for example, equal to or less than 1/29 of a distance between centers of the neighboring dielectrics, and preferably, a thickness of each dielectric may be equal to or less than 1/40 of a distance between centers of the neighboring dielectrics.

The dielectrics may be, for example, inserted into a recess portion formed on the lower surface of the lid. Here, the lower surface of the lid exposed inside the processing container, and a lower surface of the metal electrode may be disposed on a same plane. Also, the lower surface of the lid exposed inside the processing container and a lower surface of the metal electrode may be covered by a passivation protective film. Also, an average roughness about the center line in the lower surface of the lid exposed inside the processing container and a lower surface of the metal electrode may be, for example, 2.4 μm or less, and preferably, an average roughness about the center line in the lower surface of the lid exposed inside the processing container and a lower surface of the metal electrode may be 0.6 μm or less.

A metal cover electrically connected to the lid may be adhered to a region adjacent to each dielectric, in the lower surface of the lid, and a surface wave propagating portion, through which an electromagnetic wave is propagated, may be formed on a lower surface of the metal cover exposed inside the processing container. Here, a side surface of the dielectric may be adjacent to a side of the metal cover. Also, the lower surface of the metal cover exposed inside the processing container and the lower surface of the metal electrode may be disposed on a same plane. Also, a shape of the lower surface of the metal cover and a shape of the lower surface of the metal electrode may be substantially same, when viewed from the inside of the processing container. Also, an average roughness about the center line in the lower surface of the metal cover exposed inside the processing container and the lower surface of the metal electrode may be, for example, 2.4 μm or less, and preferably, the lower surface of the metal cover exposed inside the processing container and the lower surface of the metal electrode may be, for example, 0.6 μm or less.

The plasma processing apparatus may include a plurality of connecting members, which penetrate through holes formed on the dielectrics, and fix the metal electrode to the lid. Here, an elastic member, which electrically connects the lid and the metal electrode, may be disposed on at least a part of the holes formed on the dielectrics. Also, the connecting members may be, for example, formed of a metal. Also, lower surfaces of the connecting members exposed inside the processing container may be disposed on a same plane as the lower surface of the metal electrode. Also, each dielectric may have, for example a substantially tetragonal plate shape, and the connecting members may be disposed on a diagonal of the tetragon. Also, 4 connecting members may be disposed per 1 dielectric.

The plasma processing apparatus may include an elastic member, which elastically supports the dielectric and the metal electrode toward the lid.

A continuous groove, for example, may be formed on the lower surface of the lid, and the surface wave propagating portion and the plurality of dielectrics may be disposed inside a region surrounded by the groove. Here, the surface wave propagating portion may be divided by the groove. Alternatively, a continuous convex portion may be formed, for example, on an inner side of the processing container, and the surface wave propagating portion and the plurality of dielectrics may be disposed in a region surrounded by the convex portion. Here, the surface wave propagating portion may be divided by the convex portion.

The plasma processing apparatus may include one or more metal rods which are on upper portions of the dielectrics, do not penetrate through the dielectrics, have lower ends adjacent to or close to upper surfaces of the dielectrics, and transmit an electromagnetic wave to the dielectrics. Here, the metal rods may be disposed on center portions of the dielectrics. Also, the plasma processing apparatus may include a sealing member, which divides an atmosphere inside the processing container from an atmosphere outside of the processing container, between the dielectrics and the lid.

An area of exposed parts of the dielectrics may be, for example, equal to or less than ½ of an area of the surface wave propagating portion. Preferably, an area of exposed parts of the dielectrics may be equal to or less than ⅕ of an area of the surface wave propagating portion. Also, the plasma processing apparatus may include a gas discharging unit which is on the surface wave propagating portion and discharges a predetermined gas to the processing container. Also, an area of exposed parts of the dielectrics may be, for example, equal to or less than ⅕ of an area of an upper surface of the substrate. Also, a frequency of an electromagnetic wave supplied from the electromagnetic wave source may be, for example, equal to or less than 2 GHz.

### Advantageous Effects

According to embodiments of the present invention, shapes or sizes of surface wave propagating portions formed around the dielectrics exposed inside the processing container become almost the same, and the plasma excited in the processing container by the conductor surface wave becomes uniform. As a result, a uniform process is performed on the entire processing surface of the substrate. Also, it is possible to drastically reduce the used amount of dielectrics since the plasma can be excited by using the electromagnetic wave (conductor surface wave) propagated along the surface wave propagating portion disposed around the dielectrics. Also, by reducing the area of the exposed part of the dielectrics exposed inside the processing container, damage, etching, or the like of the dielectric due to overheating of the dielectric is suppressed, while generation of metal contamination from the inner side of the processing container is removed. Specifically, when an electromagnetic wave having a frequency of 2 GHz or lower is used, the lowest electron density for obtaining stable plasma having a low electron temperature may be about 1/7 compared to when the microwave having a frequency of 2.45 GHz is used, and the plasma suitable for the plasma process can be obtained under wide conditions that has not been used before, and thus general-purpose of the processing apparatus can be remarkably increased. As a result, it is possible to perform a plurality of continuous processes having different processing conditions by using one processing apparatus, and thus it is possible to manufacture a product having high quality in a short time with a low expense.

### BRIEF DESCRIPTION OF THE DRAWINGS

FIG. 1 is a longitudinal-sectional view (cross-sectional view taken along a line D-O′-O-E of FIGS. 2 through 4) schematically showing a configuration of a plasma processing apparatus according to an embodiment of the present invention;

FIG. 2 is a cross-sectional view taken along a line A-A of FIG. 1;

FIG. 3 is a cross-sectional view taken along a line B-B of FIG. 1;

FIG. 4 is a cross-sectional view taken along a line C-C of FIG. 1;

FIG. 5 is a magnified view of a portion F of FIG. 1;

FIG. 6 is a magnified view of a portion G of FIG. 1;

FIG. 7 is a plan view of a dielectric 25;

FIG. 8 is a view for describing a state of a conductor surface wave being propagated in a surface wave propagating portion;

FIG. 9 is a view for describing a propagation model of a conductor surface wave;

FIG. 10 is a view for describing a groove;

FIG. 11 is a schematic view for describing a state of plasma in a processing container during a plasma process;

FIG. 12 is a view for describing a standing wave distribution of a microwave electric field in a sheath obtained via an electromagnetic simulation;

FIG. 13 is a graph showing a microwave electric field strength distribution in a sheath taken along a line A-B of FIG. 12;

FIG. 14 is a graph showing standardized electric field strength of a corner portion of a metal cover;

FIG. 15 is a view of a lower surface of a lid of a plasma processing apparatus according to Modified Example 1;

FIG. 16 is a longitudinal-sectional view (a cross-sectional view taken along a line D-O′-O-E of FIG. 17) schematically showing a configuration of a plasma processing apparatus according to Modified Example 2;

FIG. 17 is a cross-sectional view taken along a line A-A of FIG. 16;

FIG. 18 is a longitudinal-sectional view (a cross-sectional view taken along a line D-O′-O-E of FIG. 19) schematically showing a configuration of a plasma processing apparatus according to Modified Example 3;

FIG. 19 is a cross-sectional view taken along a line A-A of FIG. 18;

FIG. 20 is a longitudinal-sectional view (a cross-sectional view taken along a line D-O′-O-E of FIG. 21) showing a schematic structure of a plasma processing apparatus according to Modified Example 4;

FIG. 21 is a cross-sectional view taken along a line A-A of FIG. 20;

FIG. 22 is a view for describing a modified example, wherein an outer edge of a dielectric is on an inner side than an outer edge of a metal electrode, in view from inside a processing container;

FIG. 23 is a view for describing a modified example, wherein a recess portion for accommodating an outer edge of a dielectric is formed on a side surface of a metal cover;

FIG. 24 is a view for describing a modified example, wherein a dielectric is inserted into a recess portion of a lower surface of a lid;

FIG. 25 is a view for describing another modified example, wherein a dielectric is inserted into a recess portion of a lower surface of a lid;

FIG. 26 is a view for describing a modified example, wherein a lid having a plane shape is exposed in the vicinity of a dielectric;

FIG. 27 is a view for describing another modified example, wherein a lid having a plane shape is exposed in the vicinity of a dielectric;

FIG. 28 is a view for describing yet another modified example, wherein a lid having a plane shape is exposed in the vicinity of a dielectric;

FIG. 29 is a view for describing a rhombic dielectric;

FIG. 30 is a view of a lower surface of a lid of a plasma processing apparatus according to a modified example using an equilateral triangular dielectric;

FIG. 31 is a view for describing a structure of a connecting member using an elastic member;

FIG. 32 is a view for describing a structure of a connecting member using a belleville spring;

FIG. 33 is a view for describing a structure of a connecting member for sealing by using an O-ring;

FIG. 34 is a view for describing a structure of a connecting member using a tapered washer;

FIG. 35 is a graph for describing a cycle of a self bias voltage generated on a substrate, when plasma doping is performed;

FIG. 36 is a view for describing a state of generating a secondary electron according to plasma doping; and

FIG. 37 is a longitudinal-sectional view schematically showing a configuration of a plasma processing apparatus according to Modified Example 5.

### EXPLANATION ON REFERENCE NUMERALS

G: substrate

1: plasma processing apparatus

2: container body

3: lid

4: processing container

10: susceptor

11: feeder

12: heater

20: exhaust port

25: dielectric

27: metal electrode

30, 46, 65: connecting member

32: space

37: O-ring

42, 52, 72: gas discharge hole

45: metal cover

55: side cover

56, 57: groove

58: side cover inner portion

59: side cover outer portion

85: microwave supplying device

86: coaxial waveguide

90: branch plate

92: metal rod

102: gas supply source

103: refrigerant supply source

### BEST MODE FOR CARRYING OUT THE INVENTION

Hereinafter, embodiments of the present invention will be described based on a plasma processing apparatus 1 using a microwave as an example of an electromagnetic wave.

(Basic Configuration of Plasma Processing Apparatus 1)

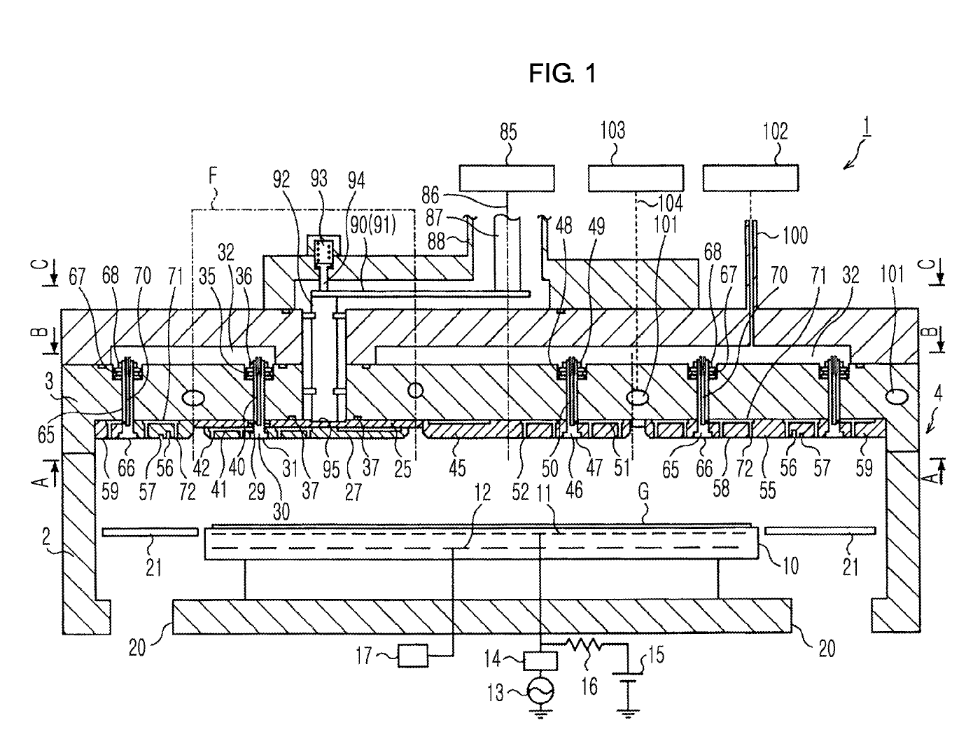

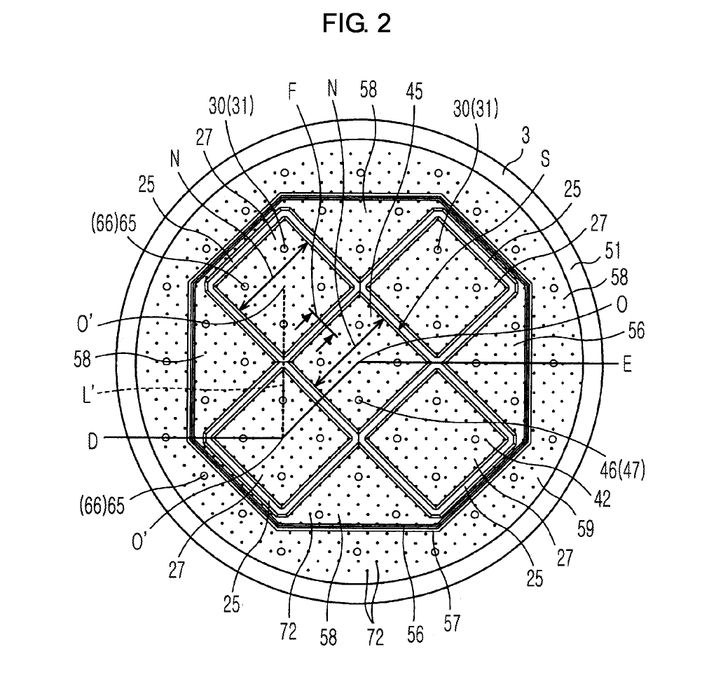

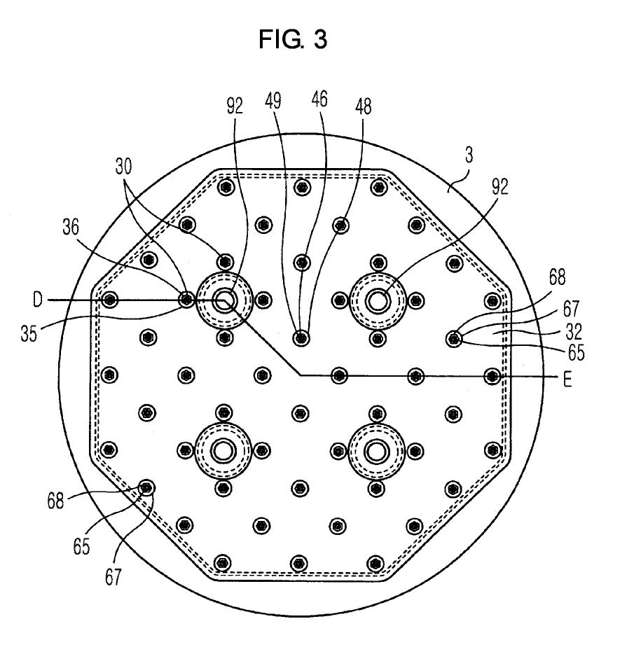

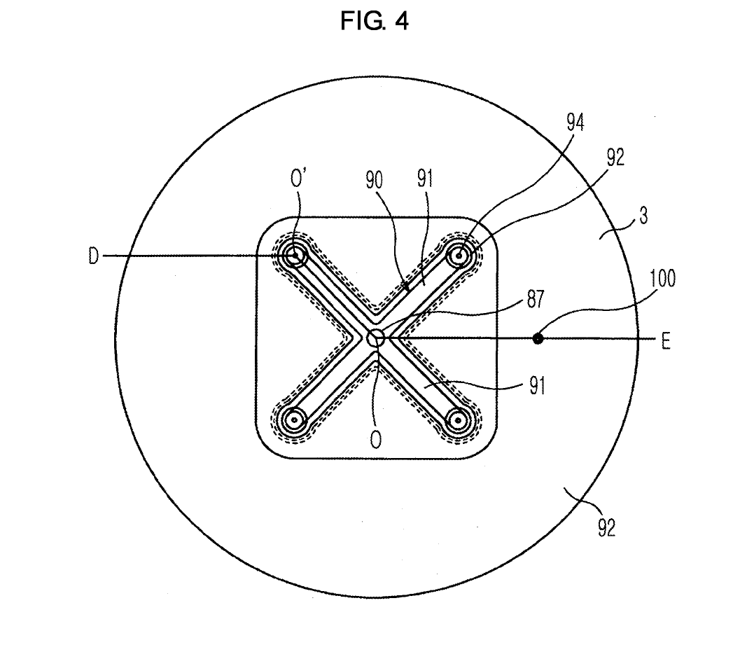

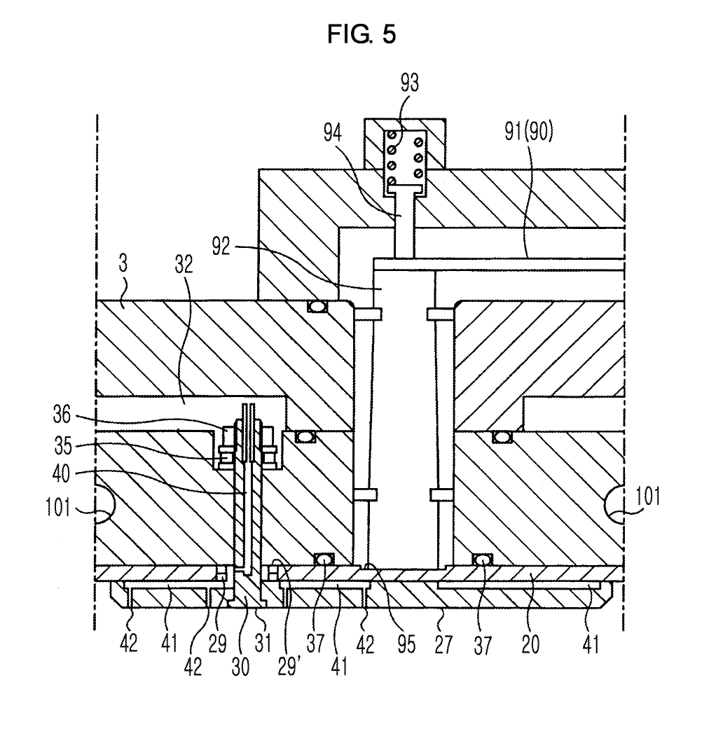

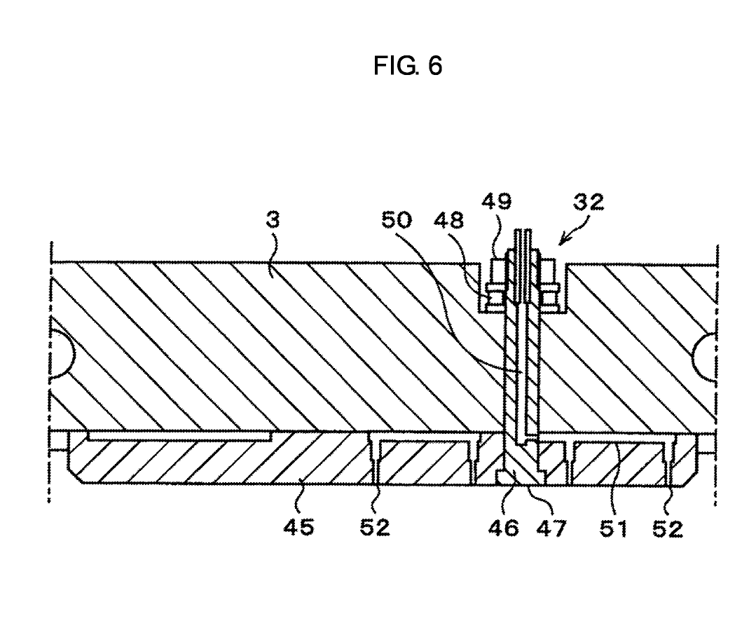

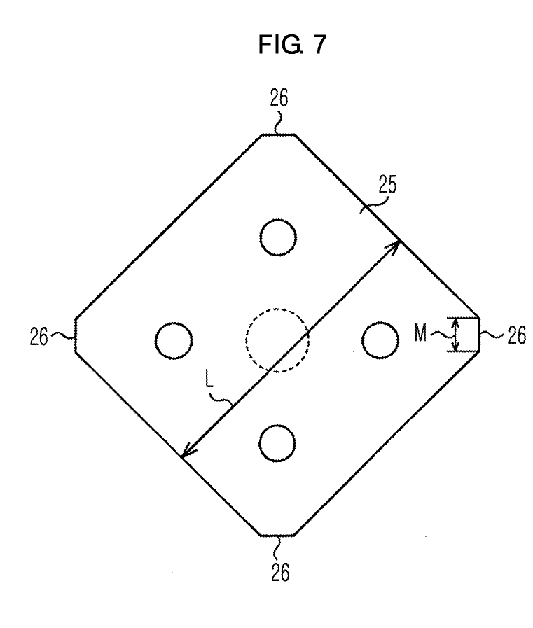

FIG. 1 is a longitudinal-sectional view (cross-sectional view taken along a line D-O′-O-E of FIGS. 2 through 4) schematically showing a configuration of the plasma processing apparatus 1 according to an embodiment of the present invention. FIG. 2 is a cross-sectional view taken along a line A-A of FIG. 1. FIG. 3 is a cross-sectional view taken along a line B-B of FIG. 1. FIG. 4 is a cross-sectional view taken along a line C-C of FIG. 1. FIG. 5 is a magnified view of a portion F of FIG. 1. FIG. 6 is a magnified view of a portion G of FIG. 1. FIG. 7 is a plan view of a dielectric 25 used in the present embodiment. In the present specification and drawings, like reference numbers denote elements having the same functions so as to omit overlapping descriptions.

The plasma processing apparatus 1 includes a processing container 4 composed of a hollow container body 2 and a lid 3 attached to an upper part of the container body 2. A sealed space is formed inside the processing container 4. The entire processing container 4 (the container body 2 and the lid 3) is formed of a conductive material, such as an aluminum alloy, and is electrically grounded.

A susceptor 10 is provided as a holding stage for holding a semiconductor substrate or a glass substrate (hereinafter, referred to as a substrate) G, inside the processing container 4. The susceptor 10 is formed of, for example, an aluminum nitride, and a feeder 11, which electrostatically absorbs the substrate G while applying a predetermined bias voltage to the inside the processing container 4, and a heater 12, which heats the substrate G to a predetermined temperature, are provided inside the susceptor 10. In the feeder 11, a high frequency power supply source 13 for bias application provided outside the processing container 4 is connected through a matcher 14 including a condenser, or the like, while a high voltage direct current power supply source 15 for electrostatic absorption is connected through a coil 16. The heater 12 is connected to an alternating current power supply source 17 provided outside the processing container 4.

An exhaust port 20 for exhausting an atmosphere in the processing container 4 by using an exhaust device (not shown), such as a vacuum pump, provided outside the processing container 4 is provided on a bottom portion of the processing container 4. Also, a baffle plate 21 for controlling a flow of gas in a preferable state inside the processing container 4 is provided around the susceptor 10.

4 dielectrics 25 formed of, for example, Al₂O₃, are attached to a lower surface of the lid 3. A dielectric material, for example, fluororesin, quartz, or the like, may be used as the dielectric 25. As shown in FIG. 7, the dielectric 25 has a square plate shape. Strictly, the dielectric 25 is an octagon since flat portions 26, which are perpendicularly cut with respect to diagonals, are formed at four corners of the dielectric 25. However, a length M of the flat portion 26 of the dielectric 25 is sufficiently short compared to a width L of the dielectric 25, and thus the dielectric 25 may be substantially considered to be a square.

As shown in FIG. 2, the 4 dielectrics 25 are disposed in such a way that vertical angles (flat portions 26) are adjacent to each other. Also, in the neighboring dielectrics 25, the vertical angles of each dielectric 25 are adjacently disposed on a line L′ connecting center points O′. As such, a square region S is formed in the center of the lower surface of the lid 3 surrounded by the 4 dielectrics 25, by adjacently disposing the vertical angles of the 4 dielectrics 25, and adjacently disposing the vertical angles of each dielectric 25 on the line connecting the center points O′ in the neighboring dielectrics 25.

A metal electrode 27 is adhered to the lower surface of each dielectric 25. The metal electrode 27 is formed of a conductive material, for example, an aluminum alloy. Like the dielectric 25, the metal electrode 27 is formed as a square plate shape. Also, in the present specification, a metal member having a plate shape attached to the lower surface of each dielectric 25 as above will be referred to as a “metal electrode”. Here, a width N of the metal electrode 27 is a little shorter than the width L of the dielectric 25. Thus, when viewed from the inside of a processing container, a surrounding portion of the dielectric 25 is exposed in a state showing a square outline, around the metal electrode 27. Also, when viewed from the inside of the processing container 4, vertical angles of the square outlines formed by the surrounding portions of the dielectrics 25 are adjacently disposed.

The dielectric 25 and the metal electrode 27 are attached to the lower surface of the lid 3 by a connecting member 30, such as a screw or the like. A lower surface 31 of the connecting member 30 exposed inside the processing container may be on the same plane as the lower surface of the metal electrode 27. Alternatively, the lower surface 31 of the connecting member 30 may not be on the same plane as the lower surface of the metal electrode 27. A spacer 29 having a ring shape is disposed in a penetrating place of the connecting member 30 with respect to the dielectric 25. An elastic member 29′, such as a wave washer, is disposed on the spacer 29, and thus upper and lower surfaces of the dielectric 25 does not have a gap. When there is an uncontrollable gap in the upper and lower surfaces of the dielectric 25, a wavelength of a microwave propagating the dielectric 25 becomes unstable, and thus uniformity of plasma may be deteriorated in general, or load impedance viewed from a microwave input side may become unstable. Also, when the gap is large, discharge may be generated. In order that the dielectric 25 and the metal electrode 27 are adhered to the lower surface of the lid 3 and is definitely electrically and thermally contacted at connecting portion, a member having elasticity may be used in the connecting portion. The elastic member 29′ may be, for example, a wave washer, a spring washer, a belleville spring, a shield spiral, or the like. A material may be a stainless steel, an aluminum alloy, or the like. The connecting member 30 is formed of a conductive metal, or the like, and the metal electrode 27 is electrically connected to the lower surface of the lid 3 through the connecting member 30 and is electrically grounded. The connecting member 30 is disposed, for example, in 4 places on a diagonal of the metal electrode 27 having a tetragonal shape.

An upper end of the connecting member 30 protrudes to a space 32 formed inside the lid 3. A nut 36 is attached to the upper end of the connecting member 30 protruding to the space 32, interposing an elastic member 35, such as a spring washer, a wave washer, or the like. The dielectric 25 and the metal electrode 27 are elastically supported to be adhered to the lower surface of the lid 3, by elasticity of the elastic member 35. Here, the adhesion of the dielectric 25 and the metal electrode 27 with respect to the lower surface of the lid 3 is easily adjusted by the nut 36.

An O-ring 37 as a sealing member is disposed between the lower surface of the lid 3 and the upper surface of the dielectric 25. The O-ring 37 is, for example, a metal O-ring. As will be described later, an atmosphere inside the processing container 4 is blocked from an atmosphere inside a coaxial waveguide 86 by the O-ring 37, and thus the atmosphere the inside the processing container 4 is separated from an atmosphere outside the processing container 4.

A longitudinal gas passage 40 is formed in the center of the connecting member 30, and a lateral gas passage 41 is formed between the dielectric 25 and the metal electrode 27. A plurality of gas discharge holes 42 are distributed and opened on the lower surface of the metal electrode 27. As will be described later, a predetermined gas supplied to the space 32 inside the lid 3 passes through the gas passages 40 and 41, and the gas discharge holes 42, and is distributed and supplied toward the inside of the processing container 4.

A metal cover 45 is attached to the region S in the center of the lower surface of the lid 3 surrounded by the 4 dielectrics 25. The metal cover 45 is formed of a conductive material, for example, an aluminum alloy, is electrically connected to the lower surface of the lid 3, and is electrically grounded. Like the metal electrode 27, the metal cover 45 has a square plate shape of the width N.

The metal cover 45 has a thickness of about a sum of thicknesses of the dielectric 25 and the metal electrode 27. Thus, the lower surface of the metal cover 45 and the lower surface of the metal electrode 27 are on the same plane.

The metal cover 45 is attached to the lower surface of the lid 3 by a connecting member 45, such as a screw or the like. A lower surface 47 of the connecting member 46 exposed inside the processing container is on the same plane as the lower surface of the metal cover 45. Alternatively, the lower surface 47 of the connecting member 46 may not be on the same plane as the lower surface of the metal cover 45. The connecting members 46 are disposed, for example, in 4 places on diagonals of the metal cover 45 having a tetragonal shape. In order to uniformly dispose gas discharge holes 52, a distance between the center of the dielectric substance 25 and the center of the connecting member 46 is ¼ of a distance L′ between the centers of the neighboring dielectrics 25.

The upper end of the connecting member 46 protrudes to the space 32 formed inside the lid 3. A nut 49 is attached to the upper end of the connecting member 46, which protrudes to the space 32 as above, interposing an elastic member 48, such as a spring washer, a wave washer, or the like. The metal cover 45 is elastically supported to be adhered to the lower surface of the lid 3 according to elasticity of the elastic member 48.

A longitudinal gas passage 50 is formed in the center of the connecting member 46, and a lateral gas passage 51 is formed between the lower surface of the lid 3 and the metal cover 45. The plurality of gas discharge holes 52 are distributed and opened on the lower surface of the metal cover 45. As will be described later, a predetermined gas supplied to the space 32 in the lid 3 is diffused and supplied toward the inside of the processing container 4 through the gas passages 50 and 51, and the gas discharge holes 52.

A side cover 55 is attached to the lower surface of the lid 3, in an outer region of the 4 dielectrics 25. The side cover 55 is formed of a conductive material, for example, an aluminum alloy, is electrically connected to the lower surface of the lid 3, and is electrically grounded. The side cover 55 also has a thickness of about the sum of thicknesses of the dielectric 25 and the metal electrode 27. Accordingly, a lower surface of the side cover 55 is on the same plane as the lower surface of the metal cover 45 and the lower surface of the metal electrode 27.

Double grooves 56 and 57 disposed to surround the 4 dielectrics 25 are formed on the lower surface of the side cover 55, and 4 side cover inner portions 58 are formed in the side cover 55 in an inner side area divided by the double grooves 56 and 57. The side cover inner portion 58 has almost the same shape as a right-angled isosceles triangle obtained by diagonally bisecting the metal cover 45 when viewed from the inside of the processing container 4. Here, a height of the isosceles triangle of the side cover inner portion 58 is a little (about ¼ of the wavelength of the conductor surface wave) longer than a height of an isosceles triangle obtained by diagonally bisecting the metal cover 45. This is because electric boundary conditions in base portions of the isosceles triangles viewed from the conductor surface wave are different in two cases.

Also, the grooves 56 and 57 have octagonal shapes when viewed from the inside of the processing container, in the present embodiment, but may also have tetragonal shapes. In this case, an area of the same right-angled isosceles triangle is formed between the corner of the tetragonal grooves 56 and 57 and the dielectric 25. Also, a side cover outer portion 59 covering a surrounding portion of the lower surface of the lid 3 is formed on the side cover 55, in an outer side area divided by the grooves 56 and 57.

As will be described later, during a plasma process, a microwave propagated to each dielectric 25 from a microwave supplying device 85 may be propagated along the lower surface of the metal cover 45, the lower surface of the metal electrode 27, and the lower surface of the side cover inner portion 58 from the vicinity of the dielectric 25 exposed to the lower surface of the lid 3. At this time, the grooves 56 and 57 operate as a propagation barrier unit so that the microwave (conductor surface wave) that was propagated along the lower surface of the side cover inner portion 58 is not propagated to an outer side (side cover outer portion 59) over the grooves 56 and 57. Accordingly in the present embodiment, the lower surface of the metal cover 45, the lower surface of the metal electrode 27, and the lower surface of the side cover inner portion 58, which are areas surrounded by the grooves 56 and 57 in the lower surface of the lid 3, become a surface wave propagating portion.

The side cover 55 is attached to the lower surface of the lid 3 by a connecting member 65, such as a screw or the like. A lower surface 66 of the connecting member 65 exposed inside the processing container is on the same plane as the lower surface of the side cover 55. Alternatively, the lower surface 66 of the connecting member 65 may not be on the same plane as the lower surface of the side cover 55.

An upper end of the connecting member 65 protrudes to the space 32 formed inside the lid 3. A nut 68 is attached to the top of the connecting member 65 protruding to the space 32 as above, interposing an elastic member 67, such as a spring washer, a wave washer, or the like. The side cover 55 is elastically supported to be adhered to the lower surface of the lid 3 by elasticity of the elastic member 67.

A longitudinal gas passage 70 is formed in a center of the connecting member 65, and a lateral gas passage 71 is formed between the lower surface of the lid 3 and the side cover 55. A plurality of gas discharge holes 72 are distributed and opened on the lower surface of the side cover 55. As will be described later, a predetermined gas supplied to the space 32 inside the lid 3 is diffused and supplied toward the inside of the processing container 4 through the gas passages 70 and 71, and the gas discharge holes 72.

A coaxial waveguide 86, which transmits the microwave supplied from the microwave supplying device 85 disposed outside the processing container 4, is connected to a surface center of the lid 3. The coaxial waveguide 86 includes an inner conductor 87 and an outer conductor 88. The inner conductor 87 is connected to a branch plate 90 disposed inside the lid 3.

As shown in FIG. 4, the branch plate 90 has a configuration in which 4 branched conductors 91 having a connected portion with the inner conductor 87 located in a center of branched conductors 91 are disposed in a cross shape. A metal rod 92 is attached to a front end lower surface of each branched conductor 91. The coaxial waveguide 86, the split plate 90, and the metal rod 92 are formed of a conductive member, such as Cu, or the like.

A press power of a spring 93 disposed on the upper portion of the lid 3 is applied to the upper end of the metal rod 92 through a supporter 94. A lower end of the metal rod 92 contacts a center of the upper surface of the dielectric 25 attached to the lower surface of the lid 3. A recess portion 95 for receiving the lower end of the metal rod 82 is formed in the center of the upper surface of the dielectric 25. The metal rod 92 is pressed down from upward without penetrating through the dielectric 25 while the lower end of the metal rod 92 is inserted into the recess portion 95 of the center of the upper surface of the dielectric 25, by the press power of the spring 93. The supporter 94 is formed of an insulator, such as Teflon (registered trademark), or the like. When the recess portion 95 is formed, reflection viewed from an input side of the microwave is suppressed, but the recess portion 95 may not be formed.

A microwave having a frequency of 2 GHz or lower, for example, 915 MHz, is introduced with respect to the coaxial waveguide 86, from the microwave supplying device 85. Accordingly, the microwave of 915 MHz is branched to the branch plate 90, and is transmitted to each dielectric 25 through the metal rod 92.

A gas pipe 100 for supplying a predetermined gas required for a plasma process is connected to the upper surface of the lid 3. Also, a refrigerant pipe 101 for supplying a refrigerant is formed inside the lid 3. A predetermined gas supplied from a gas supply source 102 disposed outside the processing container 4 through the gas pipe 100 is supplied to the space 32 inside the lid 3, and then is diffused and supplied toward the inside of the processing container 4 through the gas passages 40, 41, 50, 51, 70, and 71, and the gas discharge holes 42, 52, and 72.

A refrigerant supply source 103 disposed outside the processing container 4 is connected to the refrigerant pipe 101 through a pipe 104. A refrigerant is supplied from the refrigerant supply source 103 to the refrigerant pipe 101 through the pipe 104, thus the lid 3 is maintained as a predetermined temperature.

(Plasma Process in Plasma Processing Apparatus 1)

A case of forming a film of amorphous silicon, for example, on an upper surface of the substrate G in the plasma processing apparatus 1 according to an embodiment of the present invention comprised as above will be described. First, the substrate G is transferred into the processing container 4, and is held on the susceptor 10. Then, a predetermined plasma process is performed in the sealed processing container 4.

During the plasma process, a gas required for the plasma process, for example, a mixture gas of argon gas/silane gas/hydrogen is supplied into the processing container 4 from the gas supply source 102 through the gas pipe 100, the space 32, the gas passages 40, 41, 50, 51, 70, and 71, and the gas discharge holes 42, 52, and 72. Also, the inside of the processing container 4 is set to a predetermined pressure by being exhausted from the exhaust port 20. As described above, in the plasma processing apparatus 1 according to the present embodiment, the gas discharge holes 42, 52, and 72 are densely distributed and formed on the entire lower surface of the metal cover 45, the lower surface of the metal electrode 27, and the lower surface of the side cover 55, which are exposed in the processing container 4. Accordingly, during the plasma process, a predetermined gas is uniformly supplied from each of the gas discharge holes 42, 52, and 72 disposed on the entire lower surface of the lid 3 to the entire processing surface of the substrate G as in a shower plate, and thus it is possible to supply the predetermined gas on the entire surface of the substrate G held on the susceptor 10.

Also, while the predetermined gas is supplied into the processing container 4 as above, the substrate G is heated up to a predetermined temperature by the heater 12. Also, a microwave of, for example, 915 MHz, generated in the microwave supplying device 85 is transmitted to each dielectric 25 through the coaxial waveguide 86, the split plate 90, and the metal rod 92. Also, the microwave transmitted through each dielectric 25 is propagated along the lower surface of the metal cover 45, the lower surface of the metal electrode 27, and the lower surface of the side cover inner portion 58, which are the surface wave propagating portion, in a state of a conductor surface wave.

Here, FIG. 8 is a view for describing a state of the conductor surface wave being propagated in the lower surface of the metal cover 45, the lower surface of the metal electrode 27, and the lower surface of the side cover inner portion 58, which are the surface wave propagating portion. During the plasma process, the conductor surface wave (microwave) W is transmitted through the dielectric 25, which is exposed in a lattice shape with respect to the lower surface of the lid 3, and is propagated along the lower surface of the metal cover 45, the lower surface of the metal electrode 27, and the lower surface of the side cover inner portion 58. Here, both areas of the metal cover 45 and the metal electrode 27 are squares that are almost similar, and four sides of all of the metal cover 45 and the metal electrode 27 are surrounded at a part (surrounding portion) of the dielectric 25 exposed in the processing container. Accordingly, the conductor surface wave W transmitted through the dielectric 25 is propagated in the almost same state with respect to the metal cover 45 and the metal electrode 27. As a result, the plasma may be generated by power of the microwave under generally uniform conditions, with respect to the lower surface of the metal cover 45 and the lower surface of the metal electrode 27.

Meanwhile, while the four sides of the metal cover 45 and the metal electrode 27 are surrounded at the part (surrounding portion) of the dielectric 25 exposed in the processing container, only two sides of the side cover inner portion 58 are surrounded at the part (surrounding portion) of the dielectric 25 exposed in the processing container. Accordingly, about a half power of the conductor surface wave W is propagated to the lower surface of the side cover inner portion 58, compared to the metal cover 45 and the metal electrode 27. However, the side cover inner portion 58 has a shape that is almost similar to the right-angled isosceles triangle obtained by diagonally bisecting the side cover 55, and an area of the side cover inner portion 58 is almost a half of an area of the metal cover 45 or the metal electrode 27. Thus, the plasma is generated in the lower surface of the side cover inner portion 58 under the same conditions as in the lower surface of the metal cover 45 and the lower surface of the metal electrode 27.

Also, thinking based on the part (surrounding portion) of the dielectric 25 exposed in the processing container, as shown in FIG. 8, parts ‘a’ of the surface wave propagating portion shown as the same right-angled isosceles triangle are formed bisymmetrically on both sides of the portion of the dielectric 25 exposed in the processing container, except some parts. Accordingly, the conductor surface wave W is propagated from the parts of the dielectrics 25 exposed in the processing container under the same conditions, with respect to all parts ‘a’ of the surface wave propagating portion. As a result, the plasma may be generated according to the power of the microwave under the uniform conditions, with respect to the entire surface wave propagating portion (i.e., the entire lower surface of the metal cover 45, the lower surface of the metal electrode 27, and the lower surface of the side cover inner portion 58).

Moreover, in the plasma processing apparatus 1, the gas discharge holes 42, 52, and 72 are densely distributed and formed on the entire lower surface of the metal cover 45, the lower surface of the metal electrode 27, and the lower surface of the side cover 55, which are exposed in the processing container 4, as described above, and thus the predetermined gas may be supplied to the entire surface of the substrate G held on the susceptor 10. Thus, it is possible to perform the plasma process uniformly on the entire processing surface of the substrate G by generating the plasma by the power of the microwave under the uniform conditions with respect to the entire lower surface of the metal cover 45, the lower surface of the metal electrode 27, and the lower surface of the side cover inner portion 58, which are the surface wave propagating portion.

(Relationship Between Propagation and Frequency of Conductor Surface Wave)

Permittivity of plasma P generated in the processing container 4 is indicated as εᵣ′−jεᵣ″. The permittivity of the plasma P is expressed in a complex number due to a loss component. A real part εᵣ′ of the permittivity of the plasma P is generally smaller than −1. The permittivity of the plasma P is represented by Equation 1 below.

$${ɛ}_{γ}^{′} - {jɛ}^{″} = 1 - \frac{( {ω}_{pe} / ω )}{1 - j ( {v}_{c} / ω )} , {ɛ}_{r}^{′} < - 1 \qquad ( 1 )$$

Also, a propagation characteristic when a microwave is incident on the plasma P is represented by Equation 2 below.

$$k = {{k}_{0} ( 1 - \frac{{( {ω}_{pe} / ω )}^{2}}{1 - j ( {v}_{c} / ω )} )}^{1 / 2} \qquad ( 2 )$$

Here, k denotes a wave number, kₒ denotes a wave number in vacuum, ω denotes a microwave angular frequency, v_{c} denotes an electron collision frequency, and ωₚₑ denotes an electron plasma frequency represented by Equation 3 below.

$${ω}_{pe} = \sqrt{\frac{{e}^{2} {n}_{e}}{{ɛ}_{0} {m}_{e}}} \qquad ( 3 )$$

Here, e denotes an elementary electric charge, nₑ denotes electron density of the plasma P, ε₀ denotes vacuum permittivity, and mₑ denotes an electron mass.

A penetration length δ indicates how much microwave can be incident inside the plasma when the microwave is incident. In detail, the penetration length δ is an penetrating distance of the microwave until electric field strength E of the microwave is attenuated to 1/e of electric field strength E₀ on the boundary surface of the plasma P. The penetration length δ is represented by Equation 4 below.

δ=−1/lm(k) (4)

Here, k denotes a wave number as described above.

When the electron density nₑ is larger than a cutoff density n_{c} represented by Equation 5 below, the microwave is unable to be propagated in plasma, and thus the microwave incident on the plasma P is rapidly attenuated.

n_{c}=ε₀mₑ

ω²/e² (5)

According to Equation 4, the penetration length δ is several mm to tens of mm, and is decreased as electron density is increased. Also, when the electron density nₑ is sufficiently larger than the cutoff density n_{c}, the penetration length δ does not depend much on a frequency.

Meanwhile, a sheath thickness t of the plasma P is represented by Equation 6 below.

$$t = 0.606 {λ}_{D} \{ \frac{2 {eV}_{p}}{{k}_{B} {T}_{e}} \} \qquad ( 6 )$$

Here, Vₚ denotes plasma electrical potential, k_{B} denotes a Boltzmann constant, Tₑ denotes an electron temperature, and λ_{D} is a Debye length represented by Equation 7 below. The Debye length λ_{D} indicates how quickly disorder of electrical potential in plasma is decreased.

$${λ}_{D} = \sqrt{\frac{{ɛ}_{0} {k}_{B} {T}_{e}}{{n}_{e} {e}^{2}}} \qquad ( 7 )$$

According to Equation 6, the sheath thickness t is tens of μm to hundreds of μm. Also, it can be known that the sheath thickness t is proportional to the Debye length λ_{D}. Also in Equation 6, it is understood that the Debye length λ_{D} decreases as the electron density nₑ is increased.

┌Wavelength and Attenuation of Conductor Surface Wave┘

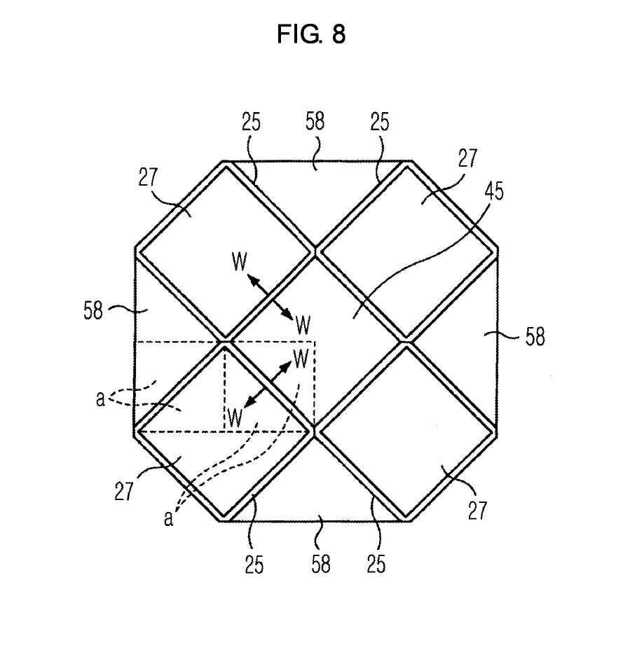

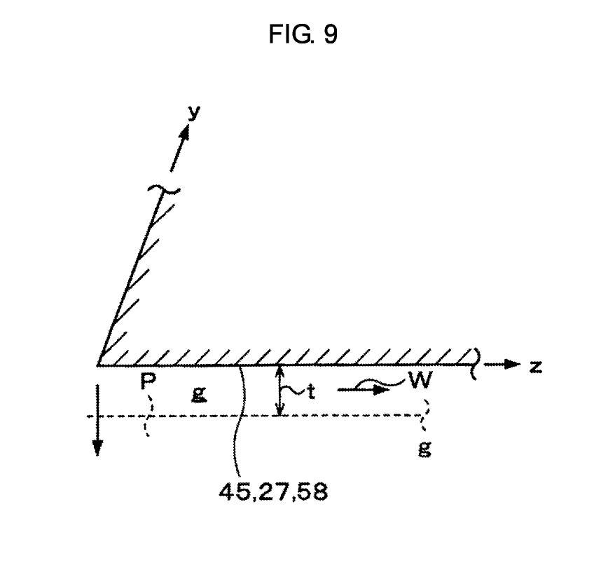

As shown in FIG. 9, a case of the conductor surface wave W propagating in a z-direction a sheath g, which is formed between the lower surface of the surface wave propagating portion (the metal cover 45, the metal electrode 27, or the side cover inner portion 58), which is a conductor, and the plasma P, is an infinitely wide and has a thickness t will be described as a propagation model of a conductor surface wave. Permittivity of the sheath g is εᵣ=1 and the permittivity of the plasma P is εᵣ′−jεᵣ″. Following is obtained when an equation which a magnetic field Hy in a y-direction of FIG. 9 satisfies is induced from Maxwell equation.

$$\frac{{\partial }^{2} {H}_{y}}{\partial {x}^{2}} + {hH}_{y} = 0 \qquad ( 8 )$$

Here, h is an eigen value, and is represented as follows in the inside and outside of a sheath.

$${h}^{2} = \{ \begin{matrix}{k}_{0}^{2} + {γ}^{2} ≡ {h}_{i}^{2} & 0 < x < t \\ ( {ɛ}_{r}^{′} - {jɛ}_{r}^{″} ) {k}_{0}^{2} + {γ}^{2} ≡ {h}_{e}^{2} & x > t ( 10 )\end{matrix} \qquad ( 9 )$$

Here, γ denotes a propagation constant, hi denotes an eigen value in the sheath g, and he denotes an eigen value in the plasma P. The eigen values hi and he are generally complex numbers.

A general solution of Equation 8 is as follows, from a boundary condition that the electric field strength in the z-direction is 0 with respect to the lower surface of the lid 3, which is a conductor.

H_{y}A cos(hᵢx)e^{-yz} 0<x<t (11)

H_{y}=Be^{-jh}^{ₑ}^{x}e^{-yz} x>t (12)

Here, A and B denote arbitrary constants.

A following characteristic equation is induced as a predetermined constant is erased by using that tangential components of a magnetic field and an electric field become continuous, in a boundary between the sheath g and the plasma P.

(ε′ᵣ−j″εᵣ)hᵢ tan(hᵢt)=jhₑ

hᵢ²−hₑ²=(1−εᵣ′+jeᵣ″)k₀² (13)

In Characteristic Equation 13, the sheath thickness t is obtained from Equation 6, and the permittivity εᵣ′−jεᵣ″ of the plasma P is obtained from Equation 1. Accordingly, by solving the Simultaneous Equation 13, the eigen values hi and he are respectively obtained. When a plurality of solutions exist, a solution where magnetic field distribution in a sheath is a hyperbolic function may be selected. Also, the propagation constant γ is obtained from Equation 9.

The propagation constant γ is represented as γ=α+jβ, by using an attenuation constant α and a phase constant β. The electric field strength E of the plasma is represented by Equation 14 below from a definition of a propagation constant.

E=E₀×e^{-jγz}=E₀e^{-αz}e^{jβz} (14)

Here, z denotes a propagation distance of a conductor surface wave TM, and E₀ denotes electric field strength when the propagation distance z is 0. e^{-αz} denotes an effect of the conductor surface wave TM being exponentially attenuated while being propagated, and e^{jβz} denotes a rotation of a phase of the conductor surface wave TM. Also, since β=2π/λc, a wavelength λc of the conductor surface wave TM is obtained from the phase constant β. Accordingly, when the propagation constant γ is known, the attenuation of the conductor surface wave TM and the wavelength λc of the conductor surface wave TM may be calculated. Also, a unit of the attenuation constant α is Np(nepper)/m, and has a following relationship with a unit (dB/m) of each graph shown later.

1 Np/m=20/ln(10)dB/m=8.686 dB/m

By using the equations above, the penetration length δ, the sheath thickness t, and the wavelength λc of the conductor surface wave TM are respectively calculated when a microwave frequency is 915 MHz, an electron temperature Te is 2 eV, plasma electrical potential Vp is 24V, and the electron density nₑ is 1×10¹¹ cm⁻³, 4×10¹¹ cm⁻³, and 1×10¹² cm⁻³. The results are shown in a following table.

TABLE 1

| | Penetration | Wavelength of | Sheath |
|---|---|---|---|
| Electron Density | Length δ | Conductor Surface Wave | Thickness |
| 1 × 10¹¹ cm⁻³ | 17.8 mm | 11.7 mm | 0.22 mm |
| 4 × 10¹¹ cm⁻³ | 8.5 mm | 23.6 mm | 0.11 mm |
| 1 × 10¹² cm⁻³ | 5.3 mm | 30.4 mm | 0.07 mm |

A conductor surface wave cannot be propagated at certain electron density or below since it is cutoff at the level of above-mentioned electron density. Such electron density is referred to as conductor surface wave resonance density nᵣ, and is twice a value of the cutoff density of Equation 5. The cutoff density is proportional to a square of a frequency, the conductor surface wave may be propagated in lower electron density as a frequency is lowered.

A value of the conductor surface wave resonance density nᵣ is 1.5×10¹¹ cm⁻³ at 2.45 GHz. Under an actual plasma processing condition, electron density near a surface may be 1×10¹¹ cm⁻³ or lower, but under such a condition, the conductor surface wave is not propagated. Meanwhile, it is 2.1×10¹⁰ cm⁻³ at 915 MHz, and thus is about 1/7 of a case of 2.45 GHz. In 915 MHz, the conductor surface wave is propagated even when electron density near a surface is 1×10¹¹ cm⁻³ or lower. As such, a frequency of 2 GHz or lower needs to be selected so as to propagate a surface wave even in low density plasma where electron density is about 1×10¹¹ cm⁻³ near a surface.

Also, attenuation of the conductor surface wave is decreased when a frequency is decreased. This is described as follows. It is known that according to Equation 1, when a frequency is decreased, the real part εᵣ′ of the permittivity of the plasma P is negatively increased, and thus plasma impedance is decreased. Accordingly, since a loss of a microwave in plasma is reduced as a microwave electric field applied to plasma is weakened compared to a microwave electric field applied to a sheath, the attenuation of the conductor surface wave TM is decreased.

When a conductor surface wave is used to generate plasma and a too high frequency is selected as a microwave frequency, uniform plasma is unable to be generated since the conductor surface wave is not propagated to a desired place. A frequency of about 2 GHz or lower needs to be selected so as to excite uniform plasma by using the conductor surface wave.

Meanwhile, in the plasma processing apparatus 1 shown in FIG. 1, when the conductor surface wave discharged from the dielectric 25 is propagated to the vicinity of the substrate G along an inner wall of the processing container 4 (inner surface of the container body 2), the plasma P generated in the processing container 4 becomes non-uniform, and thus uniformity of a process is deteriorated. In other words, according to the plasma processing apparatus 1 of the present embodiment, the uniform plasma P may be generated by the conductor surface wave that is propagated from the vicinity of the dielectric 25 to the entire surface wave propagating portion (the lower surface of the metal cover 45, the lower surface of the metal electrode 27, and the lower surface of the side cover inner portion 58), by using the microwave of 2 GHz or lower. However, when the conductor surface wave is propagated to an unsuitable location, the plasma P generated in the processing container 4 may become non-uniform. Also, when the conductor surface wave is propagated to a gate valve or a view port, an O-ring disposed near such a device may be lost or plasma may be generated right next to such a device due to energy of the conductor surface wave TM, and thus a reaction product may be attached to a surface of the device, thereby generating inconvenience. Accordingly, in the plasma processing apparatus 1 of the present embodiment, the surface wave propagating portion is formed in a region surrounded by the double grooves 56 and 57, by disposing the 4 dielectrics 25 in the inner region divided by the double grooves 56 and 57. Accordingly, the conductor surface wave is effectively propagated only to the surface wave propagating portion surrounded by the grooves 56 and 57.

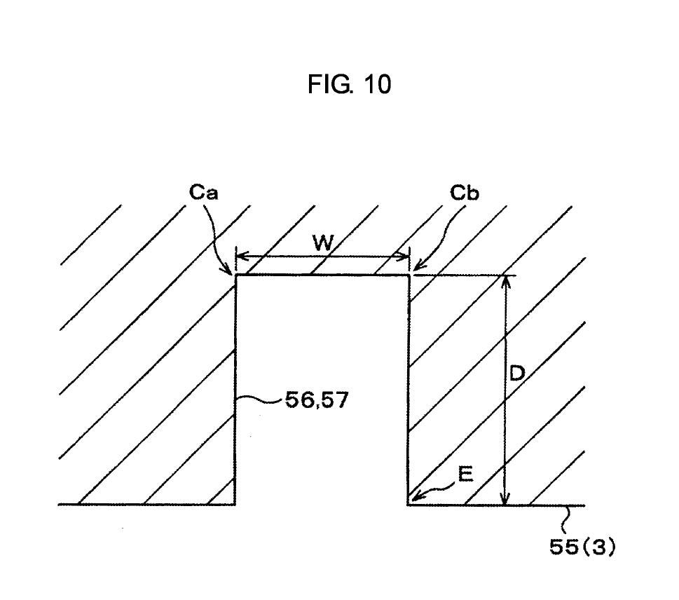

As shown in FIG. 10, when the grooves 56 and 57 having a rectangular shape cross-section are selected, an aspect ratio D/W of the grooves 56 and 57 may be determined to satisfy 0.26≦D/W≦5 so as to suppress propagation of the conductor surface wave, wherein W denotes a width of the grooves 56 and 57 and D denotes a depth of the grooves 56 and 57. Also, the width W of the grooves 56 and 57 is required to be larger than twice the sheath thickness t(2t<W), and smaller than twice the penetration length δ (2δ>W). Also, since impedance is discontinuous in a corner portion (corners Ca and Cb of FIG. 10) or an edge portion (edge E of FIG. 10) of the grooves 56 and 57, a part of the propagated conductor surface wave is reflected. When corners of the corner portion or the edge portion are rounded, discontinuity of the impedance is eased, and thus a transmission amount is increased. When a radius of curvature R of the corner portion or the edge portion is unignorably increased with respect to the wavelength of the conductor surface wave, the penetration amount is remarkably increased. The radii of curvature of the corner portion and the edge portion of the grooves 56 and 57 are required to be smaller than 1/40 of the wavelength λ of the conductor surface wave. Also, an example of forming the double grooves 56 and 57 is shown, but either the single groove 56 or 57 may suppress the propagation of the conductor surface wave.

Alternatively, a convex portion may be formed in a continuous shape instead of a groove, thereby forming the conductor surface wave in a region surrounded by the convex portion. In this case, a height of the convex portion is higher than the sheath thickness t, and is smaller than ½ of the wavelength λ of the conductor surface wave. Also, the convex portion may be single, or double or more.

(Relationship (⅕) between Area of Exposed Parts of Dielectrics 25 and Surface Area of Substrate G)

In the plasma process performed inside the processing container 4, ion incidence on the surface of the substrate G held on the susceptor 10 plays an important role. For example, in a plasma film forming process, a thin film of high quality may be quickly formed even when a temperature of the substrate G is low, by performing film forming while ions in plasma being incident on the surface of the substrate G. Also, in a plasma etching process, it is possible to accurately form a minute pattern by anisotropic etching according to perpendicular incidence of ions on the surface of the substrate G. As such, in any plasma process, it is essential to control ion incidence energy on the surface of the substrate G to an optimal value for each process so as to perform a good process. The ion incidence energy on the surface of the substrate G may be controlled by a high frequency bias voltage applied from the high frequency power supply source 13 to the substrate G through the susceptor 10.

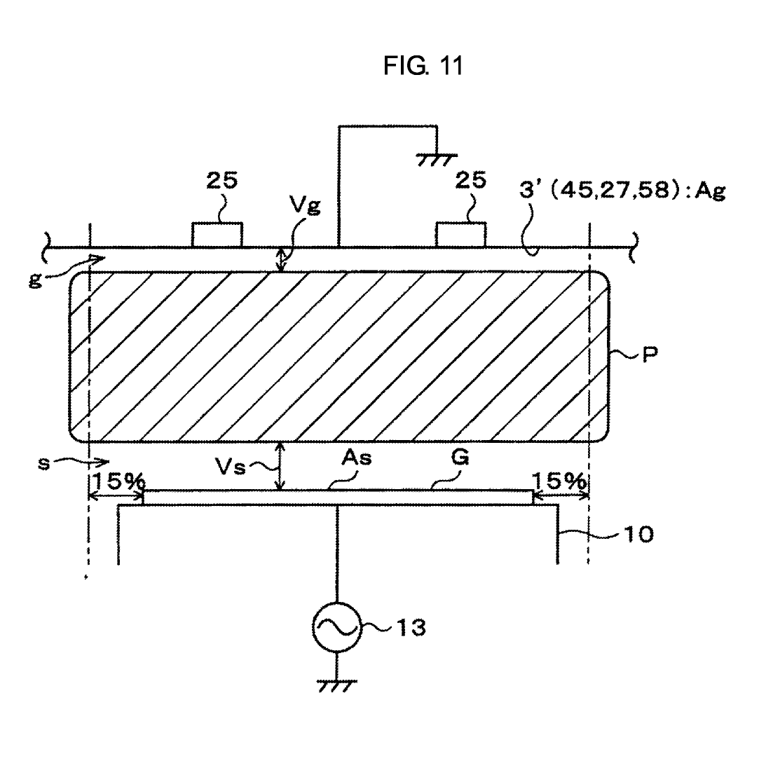

FIG. 11 is a schematic view showing a state in the processing container 4 under the plasma process, where a high frequency voltage is applied between the susceptor 10 (an electrode to which a high frequency is applied) and the lid 3 (opposite electrode=ground electrode 3′). Also, in the embodiment shown in FIG. 1 and the like, the lower surface of the metal cover 45, the lower surface of the metal electrode 27, and the lower surface of the side cover inner portion 58, which are exposed in the processing container 4 in the lower surface of the lid 3, become the ground electrode 3′. In the processing container 4 of the plasma processing apparatus 1, the plasma P of high density is generated ranging over an outer side exceeding a substrate size, above the substrate G. As such, by generating the plasma P in the range exceeding the substrate size, the plasma process may be performed uniformly on the entire upper surface (processing surface) of the substrate G. For example, when a glass substrate of 2.4 m×2.1 m is processed, a generation range of the plasma P is a region that is about 15% larger than the substrate size with respect to one side of the substrate, namely, about 30% larger than the substrate size with respect to both sides of the substrate. Accordingly, in the lower surface of the lid 3, the range of about 15% of the substrate size with respect to one side of the substrate size (about 30% with respect to both sides of the substrate size) become the ground electrode 3′ (the lower surface of the metal cover 45, the lower surface of the metal electrode 27, and the lower surface of the side cover inner portion 58).

Meanwhile, by applying a high frequency bias voltage to the substrate G from the high frequency power supply source 13, plasma sheaths g and s are formed between the plasma P and the upper surface (processing surface) of the substrate G, and between the plasma P and a part of the ground electrode 3′ of the lower surface of the lid 3 (the lower surface of the metal cover 45, the lower surface of the metal electrode 27, and the lower surface of the side cover inner portion 58), in the processing container 4 under the plasma process. The high frequency bias voltage applied from the high frequency power supply source 13 is divided and applied to each of plasma sheaths g and s.

Here, As denotes a surface area of the processing surface (upper surface) of the substrate G, Ag denotes area of a portion of the ground electrode 3′ of the lower surface of the lid 3 facing the plasma P, Vs denotes a high frequency voltage applied to the plasma sheath s between the processing surface of the substrate G and the plasma P, and Vg denotes a high frequency voltage applied to the plasma sheath g between the lower surface of the lid 3 (the lower surface of the metal cover 45, the lower surface of the metal electrode 27, and the lower surface of the side cover inner portion 58) and the plasma P. The high frequency voltages Vs and Vg, and the areas As and Ag have a relationship of Equation 15 below.

(Vs/Vg)=(Ag/As)⁴ (15)

Brian Chapman, “Glow Discharge Processes,” A Wiley Interscience Publication, 1980.

When the high frequency voltages Vs and Vg applied to the plasma sheaths s and g are increased due to an effect of an electron current flowing through the plasma sheaths s and g, a direct voltage applied to the plasma sheaths s and g is increased. An increment of the direct voltage applied to the plasma sheaths s and g is almost the same as an amplitude (0 to peak value) of the high frequency voltages Vs and Vg. Ions in the plasma P are accelerated by the direct voltage applied to the plasma sheaths s and g, and incident on the processing surface of the substrate G, which is an electrode surface, and the lower surface of the lid 3 (the lower surface of the metal cover 45, the lower surface of the metal electrode 27, and the lower surface of the side cover inner portion 58), but such an ion incidence energy may be controlled by the high frequency voltages Vs and Vg.

In the plasma processing apparatus 1 according to the present embodiment, a high frequency voltage (Vs+Vg) applied between the processing surface of the substrate G and the lower surface of the lid 3 is divided and applied to each of the plasma sheaths s and g formed near the surface of the substrate G and the lower surface of the lid 3 (the lower surface of the metal cover 45, the lower surface of the metal electrode 27, and the lower surface of the side cover inner portion 58), by the high frequency power supply source 13. Here, it is preferable to decrease the high frequency voltage Vg applied to the plasma sheath g near the lower surface of the lid 3 as much as possible so that most high frequency voltage applied from the high frequency power supply source 13 is applied to the plasma sheath s near the surface of the substrate G. This is because, when the high frequency voltage Vg applied to the plasma sheath g near the lower surface of the lid 3 is increased, not only a power efficiency is deteriorated, but also energy of ions incident on the lid 3 (the lower surface of the metal cover 45, the lower surface of the metal electrode 27, and the lower surface of the side cover inner portion 58=ground electrode 3′) is increased, and thus, the lower surface of the lid 3 (the lower surface of the metal cover 45, the lower surface of the metal electrode 27, and the lower surface of the side cover inner portion 58) is sputtered, thereby generating metal contamination. In an actual plasma processing apparatus, the high frequency voltage Vg applied to the plasma sheath g near the lower surface of the lid 3 is not practical if it is not equal to or less than ⅕ of the high frequency voltage Vs applied to the plasma sheath s near the surface of the substrate G. In other words, it can be known that the area of the part of the ground electrode 3′ of the lower surface of the lid 3 facing the plasma P (the total area of the lower surface of the metal cover 45, the lower surface of the metal electrode 27, and the lower surface of the side cover inner portion 58, i.e., the area of the surface wave propagating portion) has to be 1.5 times or above the size of the surface of the substrate G, even at the lowest, based on Equation 15.

In a conventional microwave plasma processing apparatus, since most of the lower surface of the lid 3 facing the substrate G is covered with the dielectric 25 for transmitting a microwave, an area of a ground electrode contacting high density plasma is small, specifically in a plasma processing apparatus for a large substrate. As described above, in the plasma processing apparatus 1 processing a glass substrate of, for example, 2.4 m×2.1 m, the high density plasma P is generated in the region that is about 15% larger than the substrate size with respect to one side of the substrate, namely, about 30% larger than the substrate size with respect to both sides of the substrate, and the part of the lower surface of the lid 3 facing the plasma P (the lower surface of the metal cover 45, the lower surface of the metal electrode 27, and the lower surface of the side cover inner portion 58) becomes the ground electrode 3′. For example, in the part of the ground electrode 3′, when the dielectrics 25 are all grounding portions without being exposed inside the processing container 4, the area of the ground electrode 3′ facing the plasma P is 1.7((1+0.3)²) times larger than the substrate area. However, in the conventional microwave plasma processing apparatus, since most of the ground electrode 3′ is covered by the dielectric 25, a sufficient area was not obtained. Accordingly in the conventional microwave plasma processing apparatus for a large substrate, metal contamination may be generated when a high frequency bias is applied.

Accordingly, in the plasma processing apparatus 1 according to the present embodiment, an area of the exposed surface of the dielectrics 25 exposed inside the processing container 4 is decreased as much as possible, so that the area of the exposed surface of the dielectrics 25 is suppressed to ⅕ or lower than ⅕ of the area of the upper surface of the substrate G. Also, as described above, since the plasma P is generated in the processing container 4 by using the conductor surface wave propagated along the surface wave propagating portion of the lower surface of the lid 3 (the lower surface of the metal cover 45, the lower surface of the metal electrode 27, and the lower surface of the side cover inner portion 58) in the present invention, even if the exposed area of the dielectrics 25 is small, the plasma P may be effectively generated in the entire lower surface of the ground electrode 3′. As such, when the area of the exposed surface of the dielectrics 25 contacting the plasma P is equal to or lower than ⅕ of the area of the upper surface of the substrate G, the area of the ground electrode 3′ facing the plasma P is inevitably 1.5(1.7−⅕) times larger than the area of the surface of the substrate G, even at the lowest. Accordingly, it is possible to efficiently apply the high frequency voltage applied from the high frequency power supply source 13 to the plasma sheath s near the surface of the substrate G, without generating metal contamination, which is caused because the lower surface of the lid 3 is sputtered.

(Area of Exposed Parts of Dielectrics 25 in Inside of Processing Container 4)

A microwave, which is propagated in the dielectric 25 to the end of the dielectric 25, is propagated on a metal surface adjacent to the dielectric 25 (i.e., the lower surface of the metal cover 45, the lower surface of the metal electrode 27, and the lower surface of the side cover inner portion 58) as a conductor surface wave. Here, as shown in FIG. 8, when the two parts ‘a’ of surface wave propagating portion formed at both sides of the part of the dielectric 25 exposed in the processing container 4 are formed to have symmetrical shapes, and the energy of the microwave is equally distributing to the two parts ‘a’ of the surface wave propagating portion, plasma having the same density and distribution is excited in the two parts ‘a’ of surface wave propagating portion, and thus uniform plasma is easily obtained in the entire surface wave propagating portion.

Meanwhile, plasma is excited by a dielectric surface wave even in parts where the dielectrics 25 are exposed in the processing container 4. In the dielectric surface wave, a microwave electric field is applied in both of the dielectrics 25 and the plasma, whereas in the conductor surface wave, a microwave electric field is applied only to the plasma, and thus generally, the microwave electric field of the conductor surface wave applied to the plasma is strong. Accordingly, plasma having higher density than in the surfaces of the dielectrics 25 is excited in the surface wave propagating portion (i.e., the lower surface of the metal cover 45, the lower surface of the metal electrode 27, and the lower surface of the side cover inner portion 58), which is the metal surface.

When the area of the exposed part of the dielectric 25 is sufficiently smaller than the area of the part ‘a’ of the surface wave propagating portion, uniform plasma is obtained around the substrate G due to diffusion of the plasma. However, when the area of the exposed part of the dielectric 25 is larger than the area of one portion ‘a’ of the surface wave propagating portion, i.e., when the total area of the exposed parts of the dielectrics 25 is larger than ½ of the area of the surface wave propagating portion when viewed from the entire surface wave propagating portion, not only the plasma becomes non-uniform, but also power is concentrated to the surface wave propagating portion having the small area, and thus it is highly likely that abnormal discharge or sputtering is generated. Accordingly, the area of the total sum of the exposed parts of the dielectrics 25 may be equal to or less than ½, more preferably, equal to or less than ⅕ of the area of the surface wave propagating portion.

(Thickness of Dielectric 25)

In the present embodiment, the dielectric 25 and the metal electrode 27 are attached to the lower surface of the lid 3 by the connecting member 30, and the microwave cannot be propagated in the dielectric 25 around the connecting member 30 that electrically connects the metal electrode 27 to the lid 3. The microwave that escaped the vicinity of the connecting member 30 somewhat circulates each portion of the dielectric 25 according to an effect of diffraction, but microwave electric field strength of a corner portion of the dielectric 25 tends to be weakened compared to those of other portions. Uniformity of the plasma is deteriorated if microwave electric field strength becomes too weak.

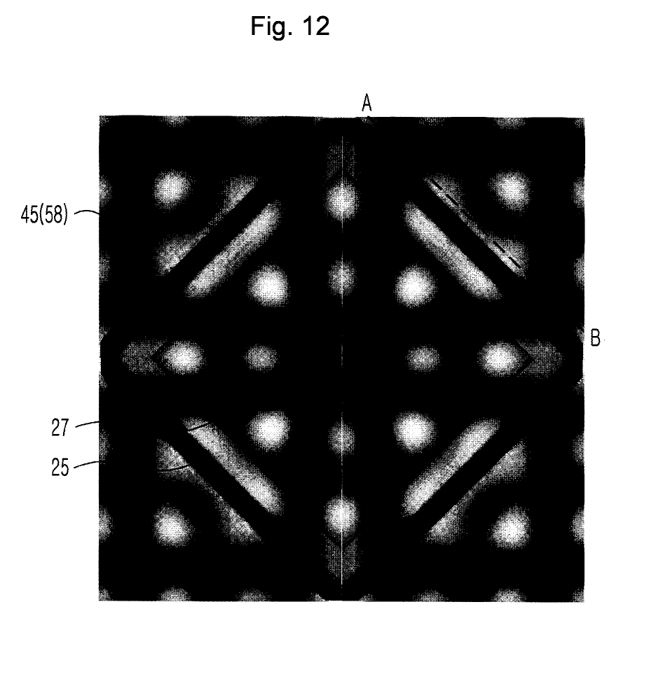

FIG. 12 shows standing wave distribution of a microwave electric field in a sheath, obtained via an electromagnetic simulation. A material of the dielectric 25 is alumina. Electron density in the plasma is 3×10¹¹ cm⁻³, and pressure in the plasma is 13.3 Pa. Also, as shown in FIG. 12, a unit including a region having a center point of the adjacent metal cover 45 as a apex (or an area obtained by bisecting the side cover inner portion 58 which performs the same functions as the area having the center point of the adjacent metal cover 45 as the apex) with one piece of metal electrode 27 as the center, is referred to as a cell. The assumed cell is a square, wherein a length of one side is 164 mm. The dielectric 25 exists in the center of the cell, while being rotated by 45° with respect to the cell. A part having a strong electric field is shown brightly. It can be known that regular, symmetrical, and 2-dimensional standing waves are generated in the lower surface of the metal electrode 27, the metal cover 45, and the lower surface of the side cover inner portion 58. These are the results obtained via a simulation, but when plasma is actually generated and observed, completely the same distribution is obtained.

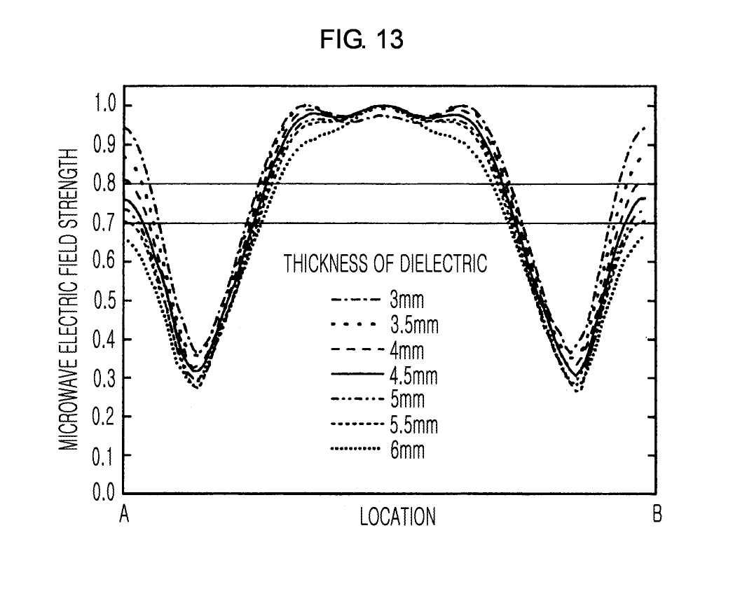

FIG. 13 shows a microwave electric field strength distribution in a sheath taken along a line A-B of FIG. 12, when a thickness of the dielectric 25 is changed from 3 mm to 6 mm. A vertical axis is standardized with respect to maximum electric field strength on the line A-B. It can be known that antinodes of the standing wave are located in the center and the end (the corner portion of the metal cover), and nodes are located therebetween. It is preferable that the electric field strengths are generally the same at the center and the end, but it can be seen that the end side is weak.

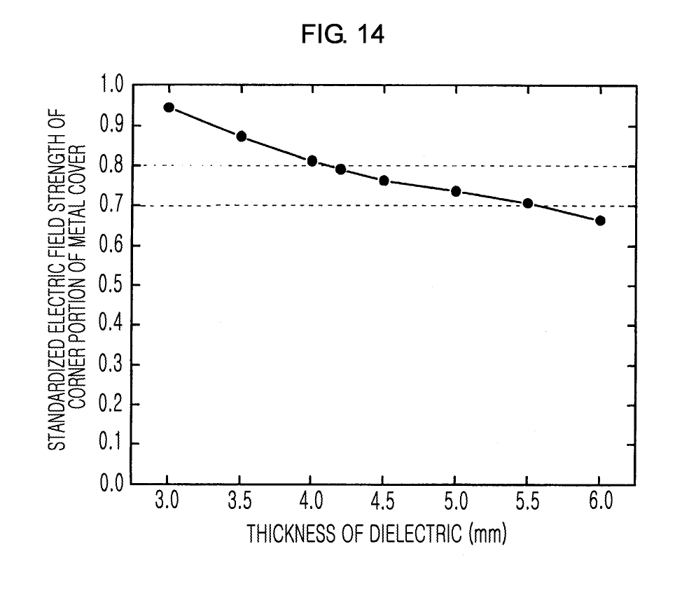

The standardized electric field strength of a corner portion of the metal cover obtained as above is shown in FIG. 14. The standardized electric field strength is 93% when the thickness of the dielectric 25 is 3 mm, but it is decreased as the thickness of the dielectric 25 is increased, and thus it is 66% at 6 mm. Considering uniformity of the plasma, the standardized electric field strength of a corner portion of the lower surface of the metal electrode 27 and a corner portion of the metal cover 45 may be preferably 70% or above, more preferably 80% or above. Referring to FIG. 12, it can be determined that the thickness of the dielectric 25 needs to be 4.1 mm or lower so that the standardized electric field strength is 70% or above, and needs to be 5.1 mm or lower so that the standardized electric field strength is 80% or above.

Strength of the microwave reaching the dielectric 25 by diffraction of the microwave propagating the dielectric 25 is dependent not only on the thickness of the dielectric 25, but also on a distance between the connecting member 30, which is a propagation obstacle, and the dielectric 25. As the distance increases, the strength of the microwave reaching the corner portion of the dielectric 25 increases. A distance between the connecting member 30 and the corner portion of the dielectric 25 is generally proportional to a distance (pitch of cell) between the centers of the dielectrics 25. Accordingly, it is good to set the thickness of the dielectric 25 to be lower with respect to the distance between the centers of the dielectrics 25. Since the pitch of the cell is 164 mm in FIG. 12, the thickness of the dielectric 25 may be equal to or less than 1/29 of the distance between the centers of the dielectrics 25 so that the standardized electric field strength is 70% or above, and may be equal to or less than 1/40 so that the standardized electric field strength is 80% or above.

(Evenness of Surface Wave Propagating Portion)

When electron density increases, microwave electric field strength applied to a sheath is increased. When there is a minute corner portion in the lower surface of the metal cover 45, the lower surface of the metal electrode 27, and the lower surface of the side cover inner portion 58, which are the surface propagation part, an electric field is concentrated in the corner portion and the corner portion is overheated, and thus an abnormal discharge (arc discharge) may be generated. When at least one abnormal discharge is generated, a discharge unit moves around while melting a metal surface, thereby significantly damaging the metal surface. When the average roughness with respect to the center line in the lower surface of the metal cover 45, the lower surface of the metal electrode 27, and the lower surface of the side cover inner portion 58, which are the surface wave propagating portion, is sufficiently smaller than a thickness of the sheath, an electric field is applied to the metal surface on average despite of the minute corner portion. Accordingly, the electric field is not concentrated, and thus an abnormal discharge is not generated.

The sheath thickness t has been described above, and the sheath thickness t is inversely proportional to a square root of the electron density. It is sufficient to assume 1×10¹³ cm⁻³ as the maximum electron density. Here, a Debye length is 3.3 μm, and in case of Ar plasma, a thickness of a sheath is 3.5 times larger, i.e., 12 μm. Electric field concentration may be ignored in each corner portion if the average roughness of the metal surface with respect to the center line is equal to or lower than ⅕ of the thickness of the sheath, more preferably, equal to or lower than 1/20. Accordingly, it may be 2.4 μm, or more preferably, 0.6 μm or lower.

### MODIFIED EXAMPLES

Hereinafter, the plasma processing apparatus 1 according to other embodiments will be described. Also, like reference numerals denote like elements as those of the plasma processing apparatus 1 described above with reference to FIG. 1, or the like, so as to omit overlapping descriptions.

### Modified Example 1

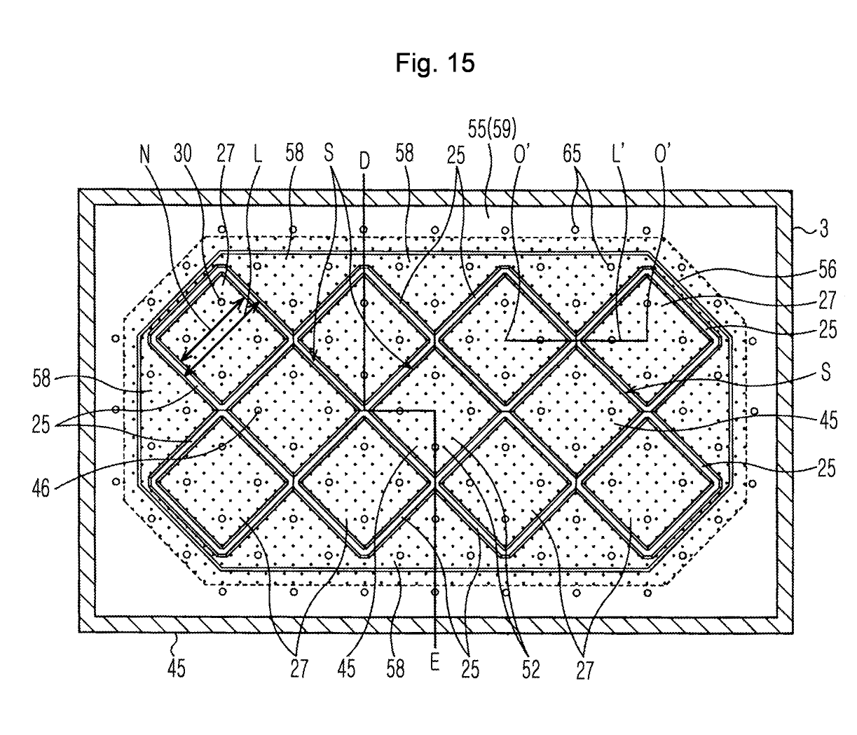

FIG. 15 is a view of a lower surface of the lid 3 of the plasma processing apparatus 1 according to Modified Example 1. In the plasma processing apparatus 1 according to Modified Example 1, 8 dielectrics 25 formed of, for example, Al₂O₃, are attached to the lower surface of the lid 3. Like above, as shown in FIG. 7, each dielectric 25 has a plate shape that may be considered substantially as a square. Each dielectric 25 is disposed in such a way that vertical angles are adjacent to each other. Also, the vertical angles of each dielectric 25 are disposed to be adjacent to each other on the line L′ connecting the center points O′ of the neighboring dielectrics 25. As such, by adjoining the vertical angles of each of the 8 dielectrics 25, and by disposing the vertical angles of each dielectric 25 adjacent to each other on the line connecting the center points O′ with respect to the neighboring dielectrics 25, the square region S surrounded by the 4 dielectrics 25 is formed on 3 places of the lower surface of the lid 3.

The metal electrode 27 is attached to the lower surface of each dielectric 25. The metal electrode 27 is formed of a conductive material, for example, an aluminum alloy. Like the dielectric 25, the metal electrode 27 has a square plate shape. However, the width N of the metal electrode 27 is a little shorter than the width L of the dielectric 25. Accordingly, when viewed from the inside of the processing container, the surrounding portion of the dielectric 25 is exposed in a state of showing a square outline, around the metal electrode 27. Also, when viewed from the inside of the processing container 4, vertical angles of the square outline formed by the surrounding portion of the dielectric 25 are disposed to be adjacent to each other.

The dielectric 25 and the metal electrode 27 are attached to the lower surface of the lid 3 by the connecting member 30, such as a screw or the like. The metal electrode 27 is electrically connected to the lower surface of the lid 3 through the connecting member 30, and is electrically grounded. A plurality of gas discharge holes 42 are distributed and opened on the lower surface of the metal electrode 27.

The metal cover 45 is attached to each region S of the lower surface of the lid 3. Each metal cover 45 is formed of a conductive material, for example, an aluminum alloy, electrically connected to the lower surface of the lid 3, and is electrically grounded. Like the metal electrode 27, the metal cover 45 has a square plate shape having the width N.

The metal cover 45 has a thickness of about a sum of thicknesses of the dielectric 25 and the metal cover 27. Accordingly, the lower surface of the metal cover 45 and the lower surface of the metal electrode 27 are on the same plane.

The metal cover 45 is attached to the lower surface of the lid 3 by the connecting member 46, such as a screw or the like. The plurality of gas discharge holes 52 are distributed and opened on the lower surface of the metal cover 45.

The side cover 55 is attached to the outer region of the 8 dielectrics 25, in the lower surface of the lid 3. The side cover 55 is formed of a conductive material, for example, an aluminum alloy, electrically connected to the lower surface of the lid 3, and electrically grounded. The side cover 55 also has a thickness of about the sum of the thicknesses of the dielectric 25 and the metal electrode 27. Accordingly, the lower surface of the side cover 55 is on the same plane as the lower surface of the metal cover 45 and the lower surface of the metal electrode 27.

A groove 56 disposed to surround the 8 dielectrics 25 is continuously formed on the lower surface of the side cover 55, and 8 side cover inner portions 58 are formed on the side cover 55 in the inner region divided by the groove 56. When viewed from the inside of the processing container 4, the side cover inner portion 58 has a shape that is almost the same as the right-angled isosceles triangle obtained by diagonally bisecting the metal cover 45. Here, a height of an isosceles triangle of the side cover inner portion 58 is a little longer (about ¼ of the wavelength of the conductor surface wave) than a height of the isosceles triangle obtained by diagonally bisecting the metal cover 45. This is because electric boundary conditions in base portions of the isosceles triangles viewed from the conductor surface wave are different in two cases.

Also, in the present embodiment, the groove 56 has an octagonal shape when viewed from inside the processing container, but may have a tetragonal shape. As such, a region of the same right-angled isosceles triangle is formed between a corner of the tetragonal groove 45, and the dielectric 25. Also, the side cover outer portion 59 covering the surrounding portion of the lower surface of the lid 3 is formed on the side cover 55, in the outer region divided by the groove 56.

During the plasma process, the microwave propagated from the microwave supplying device 85 to each dielectric 25 is propagated from the vicinity of the dielectric 25 exposed on the lower surface of the lid 3 along the lower surface of the metal cover 45, the lower surface of the metal electrode 27, and the lower surface of the side cover inner portion 58, and thus the lower surface of the metal cover 45, the lower surface of the metal electrode 27, and the lower surface of the side cover inner portion 58, which are regions surrounded by the groove 56 in the lower surface of the lid 3, become the surface wave propagating portion.

The side cover 55 is attached to the lower surface of the lid 3, by the connecting member 65, such as a screw or the like. The plurality of gas discharge holes 72 are distributed and opened on the lower surface of the side cover 55.

In the plasma processing apparatus 1 according to Modified Example 1 shown in FIG. 15, plasma is generated by power of the microwave under the uniform condition throughout the lower surface of the metal cover 45, the lower surface of the metal electrode 27, and the lower surface of the side cover inner portion 58, which are the surface wave propagating portion, and thus it is possible to perform a uniform plasma process on the entire processing surface of the substrate G. The number and locations of the dielectrics 25 attached to the lower surface of the lid 3 may be arbitrarily changed.

### Modified Example 2

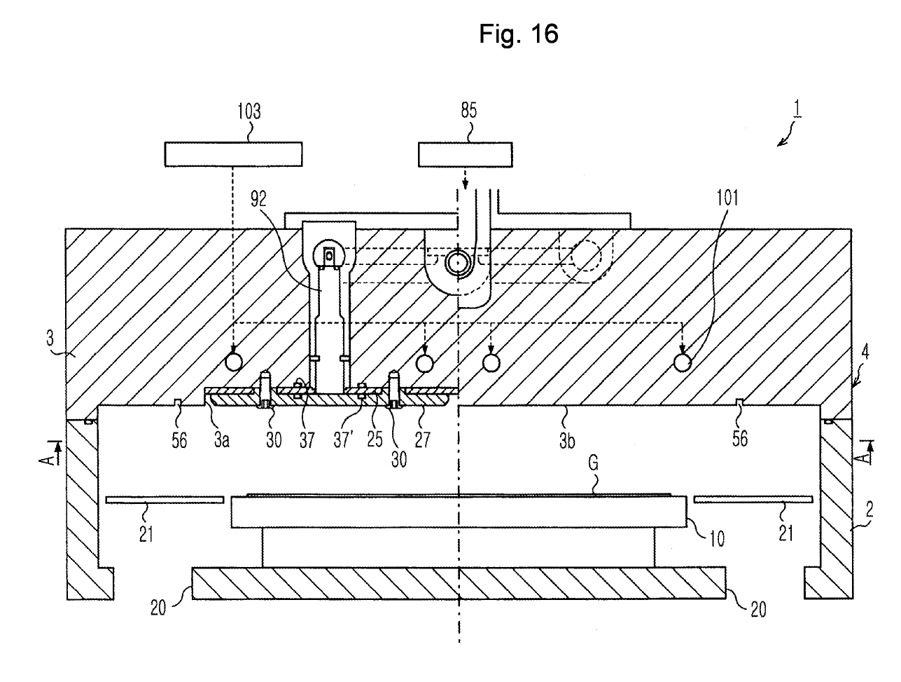

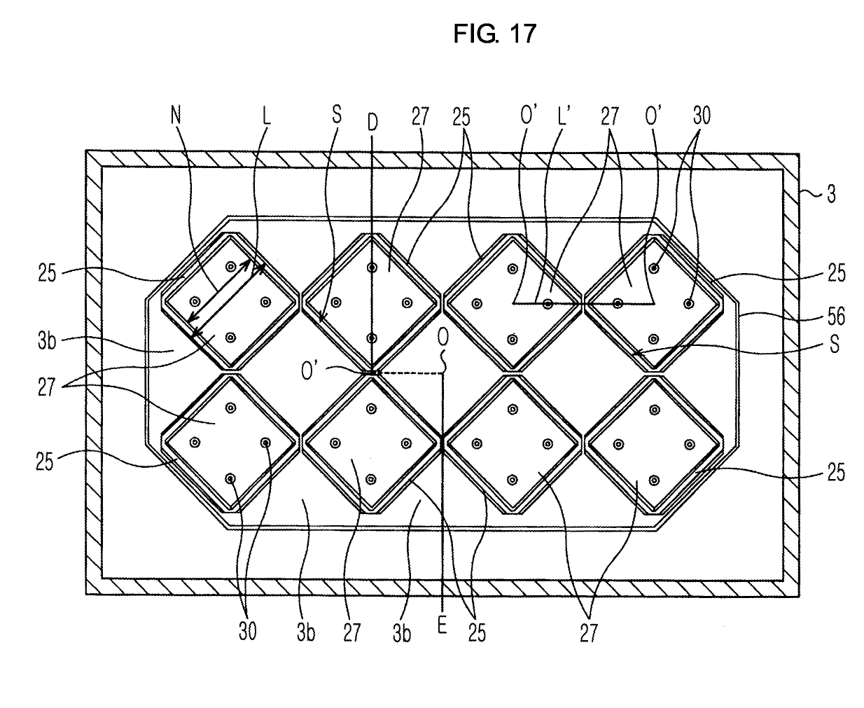

FIG. 16 is a longitudinal-sectional view (a cross-sectional view taken along a line D-O′-O-E of FIG. 17) showing a schematic configuration of the plasma processing apparatus 1 according to Modified Example 2. FIG. 17 is a cross-sectional view taken along a line A-A of FIG. 16. In the plasma processing apparatus 1 according to Modified Example 2, 8 dielectrics 25 formed of, for example, Al₂O₃, is attached to the lower surface of the lid 3. Like above, as shown in FIG. 7, each dielectric 25 has a plate shape that may be considered substantially as a square. The vertical angles of each dielectric 25 are disposed to be adjacent to each other. Also, the vertical angles of each dielectric 25 are disposed to be adjacent to each other on the line L′ connecting the center points O′ of the neighboring dielectrics 25. As such, by adjoining the vertical angles of each of the 8 dielectrics 25, and by disposing the vertical angles of each dielectric 25 to be adjacent to each other on the line connecting the center points O′ of the neighboring dielectrics 25, the square region S surrounded by the 4 dielectrics 25 is formed on 3 places of the lower surface of the lid 3.

The metal electrode 27 is attached to the lower surface of each dielectric 25. The metal electrode 27 is formed of a conductive material, for example, an aluminum alloy. Like the dielectric 25, the metal electrode 27 also has a square plate shape. However, the width N of the metal electrode 27 is a little shorter than the width L of the dielectric 25. Accordingly, when viewed from the inside of the processing container, the surrounding portion of the dielectric 25 is exposed in a state of showing a square outline, around the metal electrode 27. Also, when viewed from the inside of the processing container 4, vertical angles of the square outline formed by the surrounding portion of the dielectric 25 are disposed to be adjacent to each other.

The dielectric 25 and the metal electrode 27 are attached to the lower surface of the lid 3, by the connecting member 30, such as a screw or the like. In the present embodiment, the lower end of the metal rod 92 penetrates through the dielectric 25, and the lower end of the metal rod 92 contacts the upper surface of the metal electrode 27. Also, an O-ring 37′ as a sealing member is disposed between the lower surface of the dielectric 25 and the upper surface of the metal electrode 27 so as to surround a connecting portion between the lower end of the metal rod 92 and the upper surface of the metal electrode 27. The metal electrode 27 is connected to the lower surface of the lid 3 through the connecting member 30, and is electrically grounded.

In the present embodiment, the lower surface of the lid 3 is exposed in the processing container 4 in each region S of the lower surface of the lid 3, and the outer region of the 8 dielectrics 25. Also, recess portions 3a, into which the dielectric 25 and the metal electrode 27 are inserted, are formed on the lower surface of the lid 3. As the dielectric 25 and the metal electrode 27 are inserted into each recess portion 3a, the lower surface of the lid 3 and the lower surface of the metal electrode 27, which are exposed in the processing container 4, are on the same plane.

The groove 56 disposed to surround the 8 dielectrics 25 is continuously formed on the lower surface of the lid 3, and 8 lid lower surface inner portions 3b are formed on the lower surface of the lid 3, in the inner region divided by the groove 56. The lid lower surface inner portion 3b has a shape almost the same as a right-angled isosceles triangle obtained by diagonally bisecting the metal electrode 27, when viewed from the inside of the processing container 4.

In the plasma processing apparatus 1 according to Modified Example 2, during the plasma process, the microwave propagated from the microwave supplying device 85 to each dielectric 25 is propagated from the vicinity of the dielectric 25 exposed on the lower surface of the lid 3, along the lower surface of the metal electrode 27, each region S of the lid 3, and a lower surface of each lid lower surface inner portion 3b. Even in the plasma processing apparatus 1 according to Modified Example 2, the plasma is generated by the power of the microwave under the uniform conditions in the entire lower surface of the metal electrode 27 and each region S of the lid 3 and the lower surface of each lid lower surface inner portion 3b, which are the surface wave propagating portion, and thus it is possible to perform the uniform plasma process on the entire processing surface of the substrate G.

### Modified Example 3

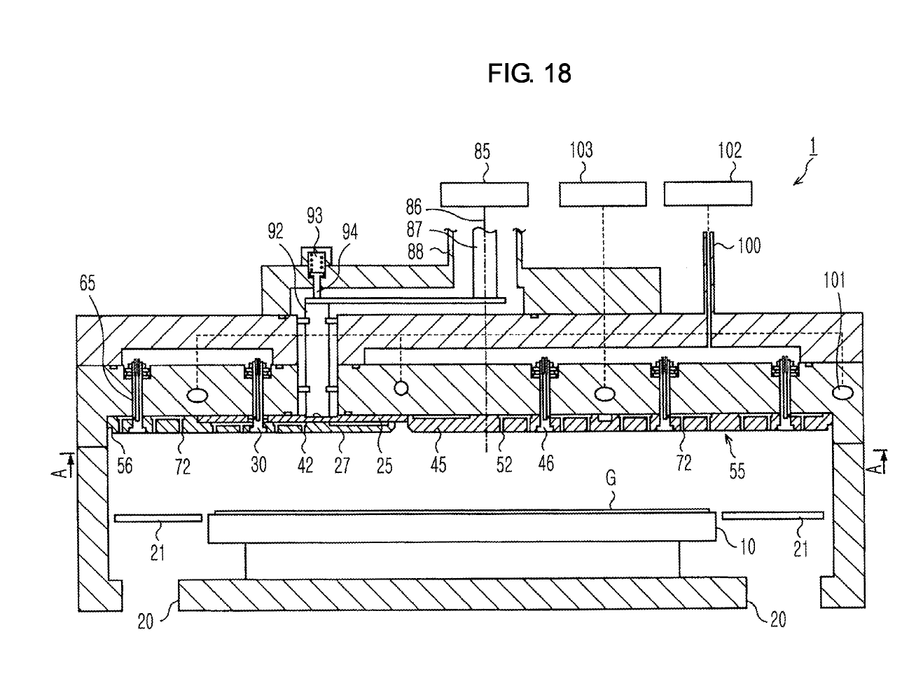

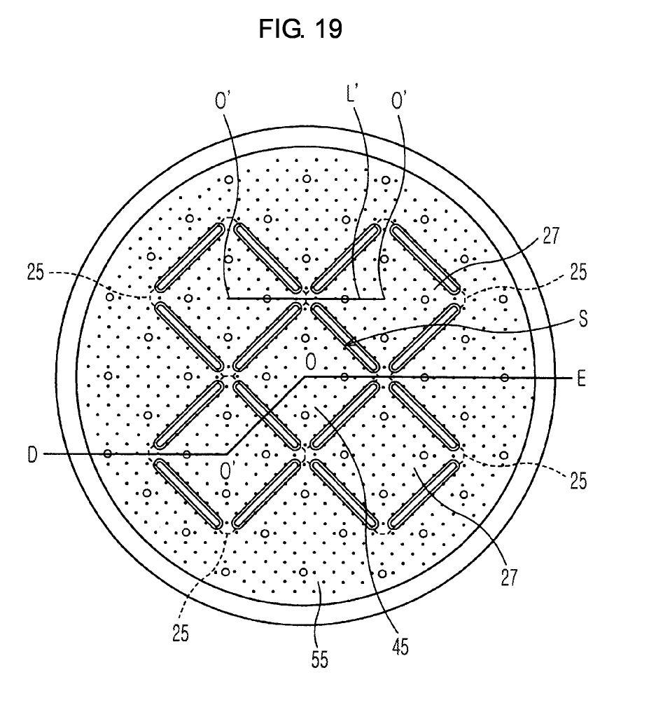

FIG. 18 is a longitudinal-sectional view (a cross-sectional view taken along a line D-O′-O-E of FIG. 19) showing a schematic configuration of the plasma processing apparatus 1 according to Modified Example 3. FIG. 19 is a cross-sectional view taken along a line A-A of FIG. 18. In the plasma processing apparatus 1 according to the Modified Example 3, 4 dielectrics 25 that are formed of, for example, Al₂O₃, are attached to the lower surface of the lid 3. Like above, as shown in FIG. 7, each dielectric 25 has a plate shape that may be considered substantially as a square. Each dielectric 25 is disposed so that vertical angles are adjacent to each other. Also, the vertical angles of each dielectric 25 are disposed to be adjacent to each other on the line L′ connecting the center points O′ of the neighboring dielectrics 25. As such, the square region S surrounded by the dielectrics 25 is formed in the center of the lower surface of the lid 3 by adjoining the vertical angles of the 8 dielectrics 25 with each other and by disposing the vertical angles of each dielectric 25 to be adjacent to each other on the line L′ connecting the center points O′ of the neighboring dielectrics 25.

In the plasma processing apparatus 1 according to Modified Example 3, the metal electrode 27 attached to the lower surface of each dielectric 25, the metal cover 45 attached to the region S, and the side cover 55 attached to the outer region of the dielectrics 25 are formed as one body. Also, the groove 56 is continuously formed on a periphery portion of the lower surface of the side cover 55, and the entire inner region divided by the groove 56 (i.e., the lower surface of the metal electrode 27, the lower surface of the metal cover 45, and the lower surface of the side cover 55) is the surface wave propagating portion.

Also by using the plasma processing apparatus 1 according to Modified Example 3, it is possible to perform a uniform plasma process on the entire processing surface of the substrate G by generating the plasma by using the power of the microwave under the uniform condition in the entire lower surface of the metal electrode 27, the lower surface of the metal cover 45, and the lower surface of the side cover 55, which are the surface wave propagating portion.

### Modified Example 4

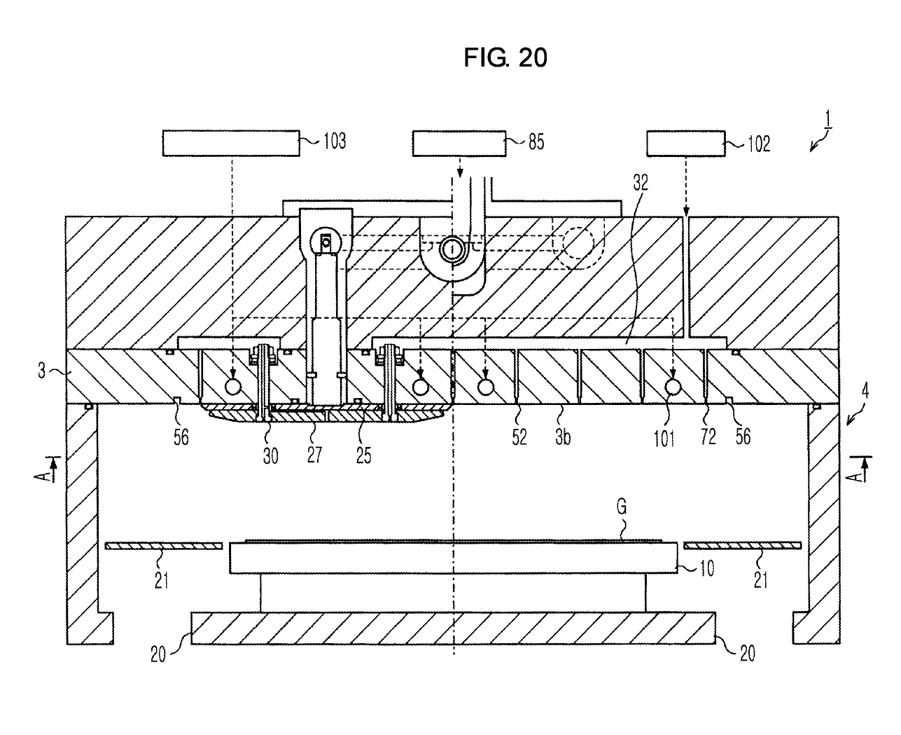

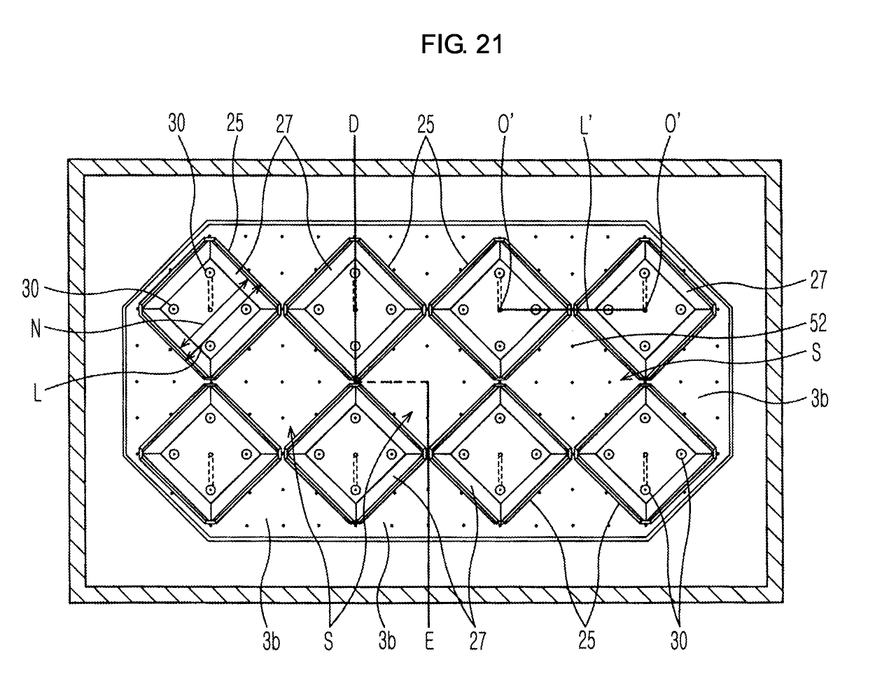

FIG. 20 is a longitudinal-sectional view (a cross-sectional view taken along a line D-O′-O-E of FIG. 21) showing a schematic configuration of the plasma processing apparatus 1 according to Modified Example 4. FIG. 21 is a cross-sectional view taken along a line A-A of FIG. 20. In the plasma processing apparatus 1 according to the Modified Example 4, 8 dielectrics 25 that are formed of, for example, Al₂O₃, are attached to the lower surface of the lid 3. Like above, as shown in FIG. 7, each dielectric 25 has a plate shape that may be considered substantially as a square. Each dielectric 25 is disposed so that vertical angles are adjacent to each other. Also, the vertical angles of each dielectric 25 are disposed to be adjacent to each other on the line L′ connecting the center points O′ of the neighboring dielectrics 25. As such, the square region S surrounded by the 4 dielectrics 25 is formed on 3 places of the lower surface of the lid 3 by adjoining the vertical angles of the 8 dielectrics 25 with each other and by disposing the vertical angles of each dielectric 25 to be adjacent to each other on the line L′ connecting the center points O′ of the neighboring dielectrics 25.

The metal electrode 27 is attached to the lower surface of each dielectric 25. The metal electrode 27 is formed of a conductive material, for example, an aluminum alloy. Like the dielectric 25, the metal electrode 27 also has a square plate shape. However, the width N of the metal electrode 27 is a little shorter than the width L of the dielectric 25. Accordingly, when viewed from the inside of the processing container 4, the surrounding portion of the dielectric 25 is exposed in a sate showing a square outline, around the metal electrode 27. Also, when viewed from the inside of the processing container 4, vertical angles of the square outlines formed by the surrounding portion of the dielectric 25 are disposed to be adjacent to each other.

The dielectric 25 and the metal electrode 27 are attached to the lower surface of the lid 3 by the connecting member 30, such as a screw or the like. The metal electrode 27 is electrically connected to the lower surface of the lid 3 through the connecting member 30, and is electrically grounded.

In the present embodiment, the lower surface of the lid 3 is in a state exposed inside the processing container 4 in each region S of the lower surface of the lid 3 and the outer region of the 8 dielectrics 25. Also, the lower surface of the lid 3 has a plane shape as a whole. Accordingly, the lower surface of the metal electrode 27 is disposed lower than the lower surface of the lid 3.

The groove 56 disposed to surround the 8 dielectrics 25 is continuously formed on the lower surface of the lid 3, and the 8 lid lower surface inner portions 3b are formed on the lower surface of the lid 3 in the inner region divided by the groove 56. The lid lower surface inner portion 3b has a shape that is almost the same as a right-angled isosceles triangle obtained by diagonally bisecting the metal electrode 27, when viewed from the inside of the processing container 4. Also, the plurality of gas discharge holes 52 are distributed and opened on each region S of the lower surface of the lid 3, and the plurality of gas discharge holes 72 are distributed and opened on each lid lower surface inner portion 3b.

In the plasma processing apparatus 1 according to Modified Example 4, during the plasma process, the microwave propagated from the microwave supplying device 85 to each dielectric 25 may be propagated from the vicinity of the dielectric 25 exposed to the lower surface of the lid 3, along the lower surface of the metal electrode 27, each region S of the lid 3, and the lower surface of the lid lower surface inner portion 3b. Also by using the plasma processing apparatus 1 according to Modified Example 4, it is possible to perform a uniform plasma process on the entire processing surface of the substrate G by generating the plasma by using the power of the microwave under the uniform condition, in the lower surface of the metal electrode 27 and each region S of the lid 3 and the entire lower surface of each lid lower surface inner portion 3b, which are the surface wave propagating portion.

(Location of Outer Edge of Dielectric)

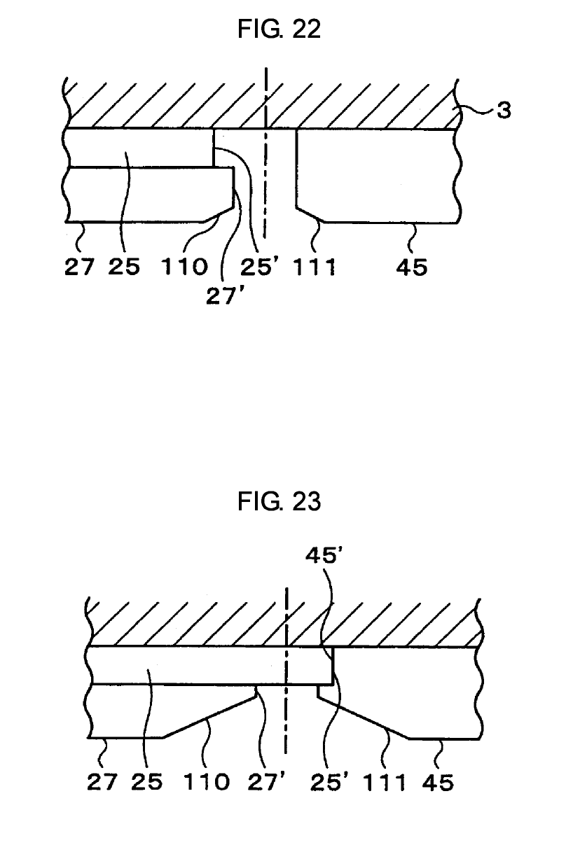

FIG. 1, etc. show an example wherein an outer edge of the dielectric 25 is on an outer side than an outer edge of the metal electrode 27, and is adjacent to the side surface of the metal cover 45. Here, FIGS. 22 through 28 are cross-sectional views showing shapes of outer edge portions of the dielectric 25, the metal electrode 27, and the metal cover 45 (a metal cover 45a) (a location of a cross-section corresponds to a cross-section F in FIG. 2). As shown in FIG. 22, an outer edge 25′ of the dielectric 25 may be on an inner side than an outer edge 27′ of the metal electrode 27 when viewed from the inside of the processing container 4, which only the side (the outer edge 25′) of the dielectric 25 is exposed inside the processing container 4. Alternatively, the outer edge 25′ of the dielectric 25 may be on the same location as the outer edge 27′ of the metal electrode 27 when viewed from the inside of the processing container 4.

Also, as shown in FIG. 23, when the outer edge 25′ of the dielectric 25 is on an outer side than the outer edge 27′ of the metal electrode 27, a recess portion 45′ for accommodating the outer edge 25′ of the dielectric 25 may be formed on the side surface of the metal cover 45.

(Shape of Lower Surface of Lid)

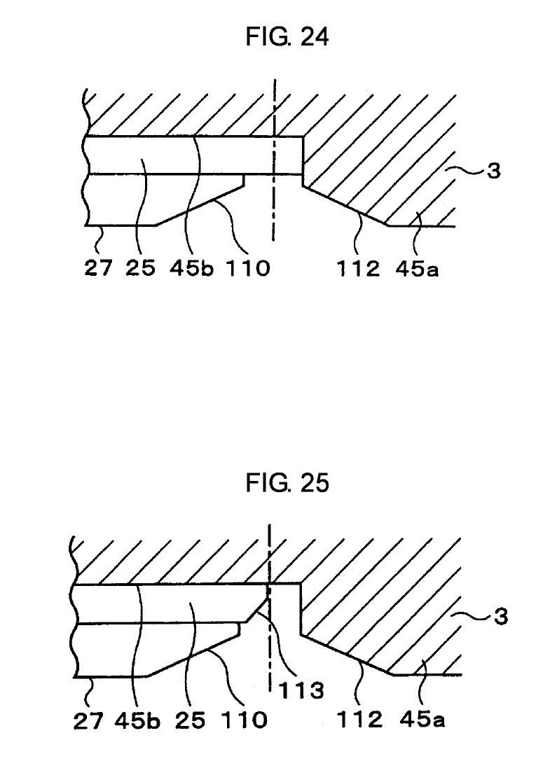

FIG. 1, etc. show an example wherein the lid 3 and the metal cover 45 having plane shapes are attached. As shown in FIGS. 24 and 25, the metal cover 45a having the same shape as the metal cover 45 may be integrally formed on the lid 3, and the dielectric 25 may be inserted into a recess portion 45b formed to be adjacent to the metal cover 45a on the lower surface of the lid 3. Here, the average roughness of the lower surface of the metal cover 45a about the center line may be 2.4 μm or lower, more preferably, 0.6 μm or lower.

Also, as shown in FIG. 24, the outer edge of the dielectric 25 may be adjacent to the side surface of the metal cover 45a, or as shown in FIG. 25, the outer edge of the dielectric 25 may be away from the side surface of the metal cover 45a.

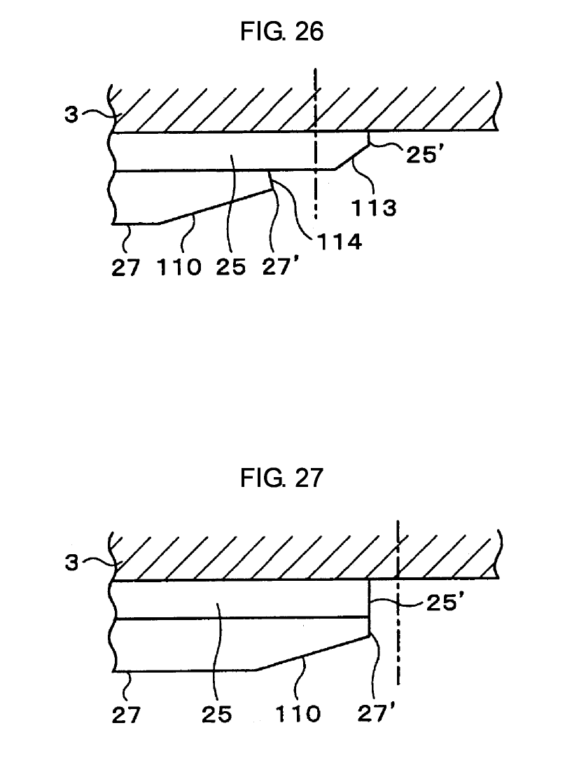

Alternatively, the metal cover 45 and the side cover 55 may be omitted, and as shown in FIGS. 26 through 28, the lower surface of the lid 3 having the plane shape may be exposed in the vicinity of the dielectric 25. Here, when viewed from the inside of the processing container 4, the shape of the lower surface of the lid 3 surrounded by the plurality of dielectrics 25, and the shape of the lower surface of the metal electrode 27 attached to the dielectric 25 may be substantially the same. Also, the average roughness of the lower surface of the lid 3 about the center line may be 2.4 μm or lower, more preferably, 0.6 μm or lower.

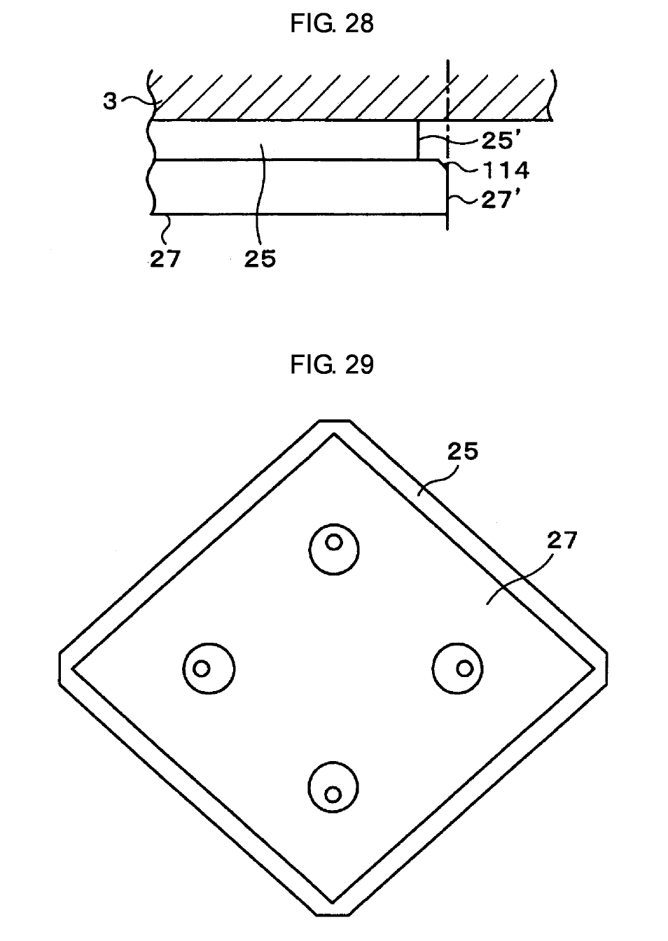

Alternatively, as shown in FIG. 26, the outer edge 25′ of the dielectric 25 may be on an outer side than the outer edge 27′ of the metal electrode 27, when viewed from the inside of the processing container 4. Alternatively, as shown in FIG. 27, the outer edge 25′ of the dielectric 25 may be at the same location as the outer edge 27′ of the metal electrode 27, when viewed from the inside of the processing container 4. Alternatively, as shown in FIG. 28, the outer edge 25′ of the dielectric 25 may be on an inner side than the outer edge 27′ of the metal electrode 27, when viewed from the inside of the processing container 4. In addition, as shown in FIGS. 22, 23, 24, 25, 26, and 27, a tapered portion 110 may be formed on the outer edge 27′ of the metal electrode 27. Also, as shown in FIGS. 22 and 23, a tapered portion 111 may be formed on the outer edge of the metal cover 45. Also, as shown in FIGS. 24 and 25, a tapered portion 112 may be formed on the outer edge of the metal cover 45a, which is formed as one body with the lid 3. Also, as shown in FIGS. 25 and 26, a tapered portion 113 may be formed on the outer edge of the dielectric 25. Also, as shown in FIGS. 26 and 28, an inverse tapered portion 114 may be formed on the outer edge 27′ of the metal electrode 27.

(Shape of Dielectric and Metal Electrode)

FIG. 1, etc. show an example of the square dielectric 25. As shown in FIG. 29, the rhombic dielectric 25 may be used. Here, when the metal electrode 27 attached to the lower surface of the dielectric 25 has a slightly smaller rhombic shape that is similar to the shape of the dielectric 25, the surrounding portion of the dielectric 25 is exposed inside the processing container 4 in a state showing a rhombic outline, in the vicinity of the metal electrode 27. A distance between the center of the dielectric 25 and the center of the connecting member 30 is set to be shorter than ¼ of the distance L′ between the centers of the neighboring dielectrics 25, but they may be the same.

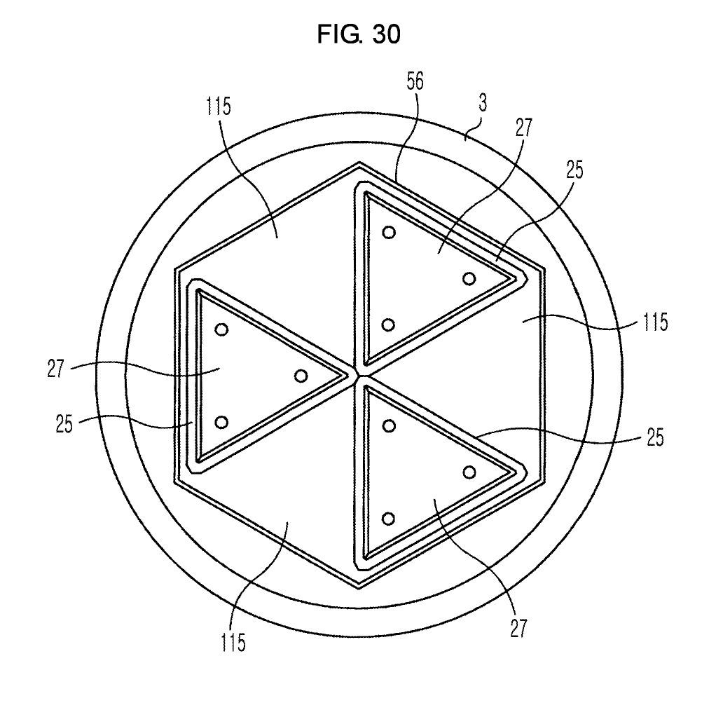

Alternatively, as shown in FIG. 30, the equilateral triangle dielectric 25 may be used. Here, when the metal electrode 27 attached to the lower surface of the dielectric 25 has an equilateral triangle that is slightly smaller than the dielectric 25 and similar to the shape of the dielectric 25, the surrounding portion of the dielectric 25 is in a state showing an equilateral triangle outline, in the vicinity of the metal electrode 27. Also, when such an equilateral triangle dielectric 25 is used, if the vertical angles of the 3 dielectrics 25 are disposed to be adjacent to each other so that the central angles are the same, a surface wave propagating portion 115 having the same shape as the metal electrode 27 may be formed between dielectrics 25.

(Structure of Connecting Member)

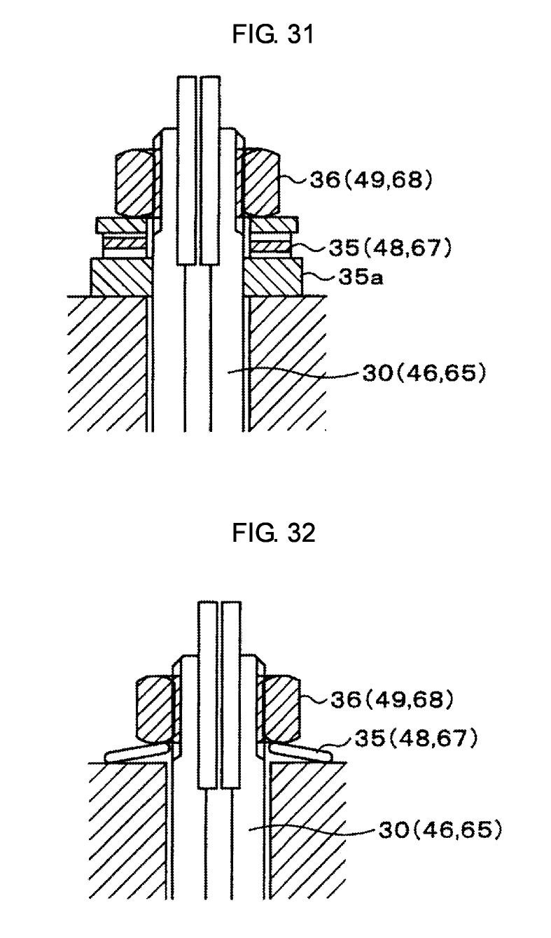

Also, as described above, the dielectric 25 and the metal electrode 27 are attached by the connecting member 30 in the lower surface of the lid 3. Here, as shown in FIG. 31, a gap between a lower washer 35a disposed below the elastic member 35 and a screw (connecting member 30) is required to be small. Also, a wave washer, a belleville spring, a spring washer, a metal spring, or the like is used as the elastic member 35. Alternatively, the elastic member 35 may be omitted.

FIG. 32 shows a type using a belleville spring as the elastic member 35. Since spring power of the belleville spring is strong, the belleville spring may generate sufficient power to press the O-ring 37. Gas leakage may be suppressed since upper and lower corners of the belleville spring are adhered to the nut 36 and the lid 3. A material of the belleville spring may be a Ni-plated SUS, or the like.

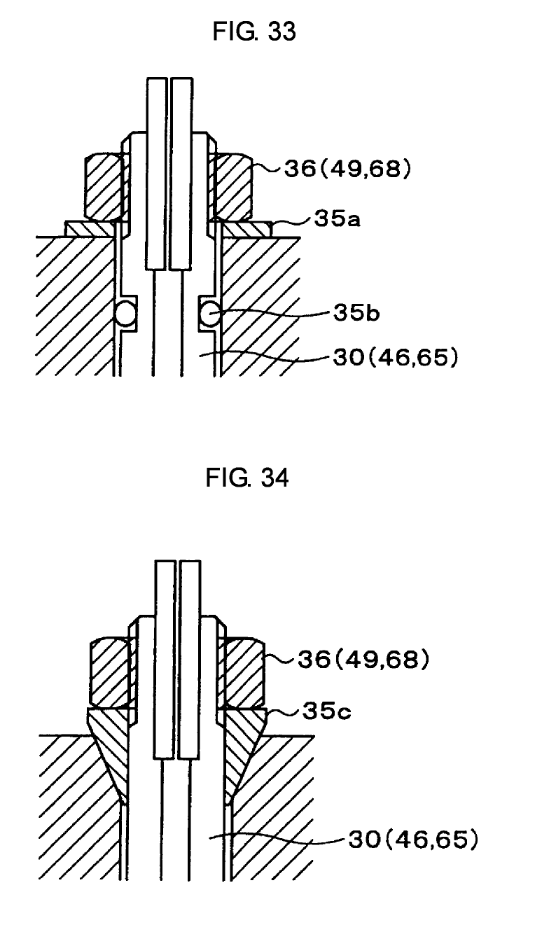

FIG. 33 shows a sealing type using an O-ring 35b. Gas leakage may be removed. The O-ring 35b may be disposed at a corner on a hole. An elastic member, such as a wave washer, a belleville spring, or the like, may be used with the O-ring 35b. In order to seal, a seal washer may be used instead of the O-ring 35b.

FIG. 34 shows a type using a tapered washer 35c. When the nut 36 is strongly tightened, the tapered washer 35c, the lid 3 and the screw (connecting member 30) are adhered to one another and a gap is removed. Accordingly sealing is definitely performed. Also, since the screw (connecting member 30) is fixed to the lid 3 by the tapered washer 35c, the screw (connecting member 30) does not rotate with the nut 36 while tightening the nut 36. Accordingly, generation of a scratch on a surface, or peeling off of a protective film formed on the surface as the screw (connecting member 30), the metal electrode 27, or the like graze each other may be prevented. A material of the tapered washer 35c may be a metal or a resin.

The connecting member 30 for fixing the dielectric 25 and the metal electrode 27 has been described, but the same may be applied to the connecting member 46 for fixing the metal cover 45 and the connecting member 65 for fixing the side cover 55. Also, although a rotation preventing function of the screw (connecting member 30) is not shown in the types of FIGS. 31 through 34, the screw (connecting member 30) may be fixed to the metal electrode 27, or the like via press-in, heat assembly, welding, adhesion, or the like, or the screw (connecting member 30) may be formed as one body with the metal electrode 27, or the like. Alternatively, a key groove may be formed between the screw (connecting member 30) and the lid 3, and rotation may be prevented by inserting a key. Alternatively, a hexagon portion or the like may be formed on the end (top) portion of the screw (connecting member 30), and the screw (connecting member 30) may be tightened while pressing the hexagon portion with a wrench or the like.

(Plasma Doping Process)

Also, a plasma doping process (ion injecting process) may be performed by using a plasma processing apparatus of the present invention. Here, in an RLSA plasma processing apparatus, since a lower surface of a lid is covered by an upper dielectric, an opposite electrode with respect to a susceptor does not exist above a substrate, and thus a chamber wall serves as a ground. Thus, it is required to straightly draw ions to the substrate by providing a ground plate operating as an opposite electrode, above the substrate, in the RLSA plasma processing apparatus. However, when the ground plate is provided in plasma, ions going to the substrate collide with the ground plate, thereby damaging the ground plate to generate heat. In other words, due to efficiency of ions lowered by plasma doping, sputtering and heat converted by collision, contamination is generated.

In this behalf, according to the plasma processing apparatus of the present invention, the exposed area of the dielectric 25 exposed inside the processing container 4 is small, and the most of the lower surface of the lid 3 exposed in the upper part in the processing container 4 is a metal surface. Accordingly, almost all of the lower surface of the lid 3 functions as a ground electrode, and thus even when a ground electrode is omitted, it may be considered that plasma doping (ion injection) is easily performed in perpendicular with respect to the upper surface of the substrate G.

Also, electric potential can be controlled since a negative DC may be applied when a ground plate is provided, and thus a depth of plasma doping may be controlled. Accordingly, in the plasma processing apparatus of the present invention, a case of controlling the depth of the plasma doping may be considered when performing the plasma doping process by providing a ground plate.

For example, in the plasma processing apparatus 1 described with reference to FIG. 1, when plasma doping is performed with respect to the substrate G, AsF₃ and BF₃ are diffused and supplied as gases for plasma excitation and doping from the gas supply source 102 into the inside of the processing container 4 through each of the gas discharge holes 42, 52, and 72 of lower surface of the metal cover 45, the lower surface of the metal electrode 27, and the lower surface of the side cover 55, as in state like in a shower plate (a rare gas, such as Ar, as a predetermined gas for plasma excitation, and a AsF₃ or BF₃ gas, as a predetermined gas for doping, may be mixed and supplied). Also, the microwave of, for example, 915 MHz, is supplied from the microwave supplying device 85, and plasma is excited with respect to the entire surface wave propagating portion (the lower surface of the metal cover 45, the lower surface of the metal electrode 27, and the lower surface of the side cover inner portion 58). Accordingly, AsF₃(→AsF₂⁺+FF⁻) and BF₃(→BF₂⁺+F⁻), and AsF₂⁺ or BF₂⁺ ions, which are doping ions, are generated. Then, a high dose amount of about 1×10¹⁵ cm⁻² is divided by about a hundred thousand times and injected, and generation of a damage is completely suppressed by removing a surface static charge generated during injection by using electrons in the plasma and injecting a high dose that is essential in forming a source and drain region of an MOS transistor.

Also, since it is required to give energy to ions reaching the substrate G, a magnetic bias voltage is generated on the substrate G by applying RF power from the high frequency power supply source 13 to the feeder 11 installed in the susceptor 10. Here, it is possible to generate a negative self-bias on the surface of the substrate G substantially without increasing plasma electric potential of a time average, since the lower surface of the lid 3 (the lower surface of the side cover 55, the lower surface of the metal cover 45, and the lower surface of the metal electrode 27) exposed on the upper part in the processing container 4 functions as the ground surface when the RF power is applied to the substrate G.

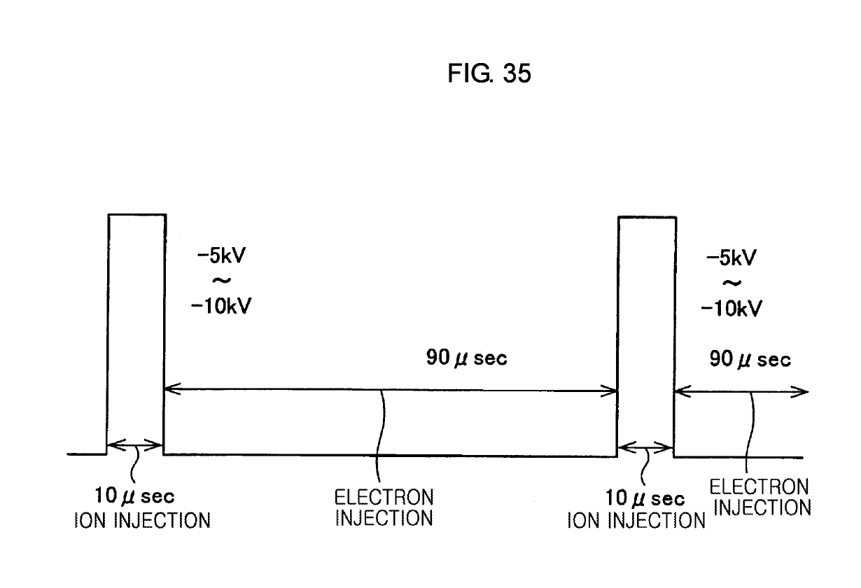

Here, as shown in FIG. 35, a negative bias of about −5 kV to −10 kV is generated on the surface of the substrate G on the susceptor 10 in about 10 μsec so as to perform ion injection, and then the static charge generated on the surface is completely erased in about 90 μsec via electron injection from the plasma. By repeating this process for hundred thousand times (10 seconds), the dose amount becomes high at about 1×10¹⁵ cm⁻².

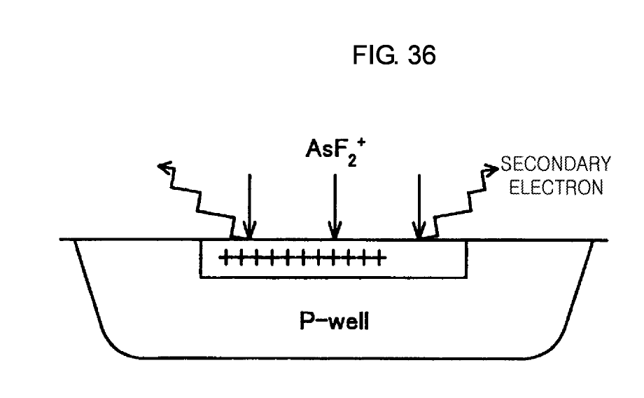

The total dose amount becomes 1×10¹⁵ cm⁻². When this is divided by hundred thousand times, one dose amount is 1×10¹⁰ cm⁻². Here, as shown in FIG. 36, secondary electrons are generated via ion injection, but considering that 10 secondary electrons are generated via one ion injection, surface generation static charge density is 1.1×10¹¹ unit/cm². Such a static charge amount is an amount in which electrons of n-region of density of 1×10¹⁷ cm⁻³ are all recombined and removed by a thickness of 11 nm. The static charge is removed via electron injection from the plasma during 90 μsec. Also, a cycle (period of ion injection/electron injection) of negative bias generated on the surface of the substrate G on the susceptor 10 may be, of course, 20 μsec/80 μsec, instead of 10 μsec/90 μsec. Also, a substrate bias of from −5 Kv to −10 kV may be generated by applying a high frequency pulse of about 1 MHz to the feeder 11.

When the plasma doping is performed, damage is not generated at all if an electric field is about 17 kV/cm. The high dose amount is injected after being divided by about hundred thousand times, and damage-free ion injection may be generated via new ion injection of removing static charge every time the high dose amount is injected.

When a dose amount of 1×10¹⁵ cm⁻² is continuously injected, accumulated static charge becomes 1.1×10¹⁶ unit/cm² and a generated electric field becomes E=1.7×10⁹ V/cm=1.7×10⁶ kV/cm, which exceeds 300 kV/cm of dielectric breakdown electric field strength of Si by far, and thus strong damage is generated. Accordingly, ions should be injected after minutely dividing the amount of ions into a minute amount so as to remove generated static charge.

### Modified Example 5

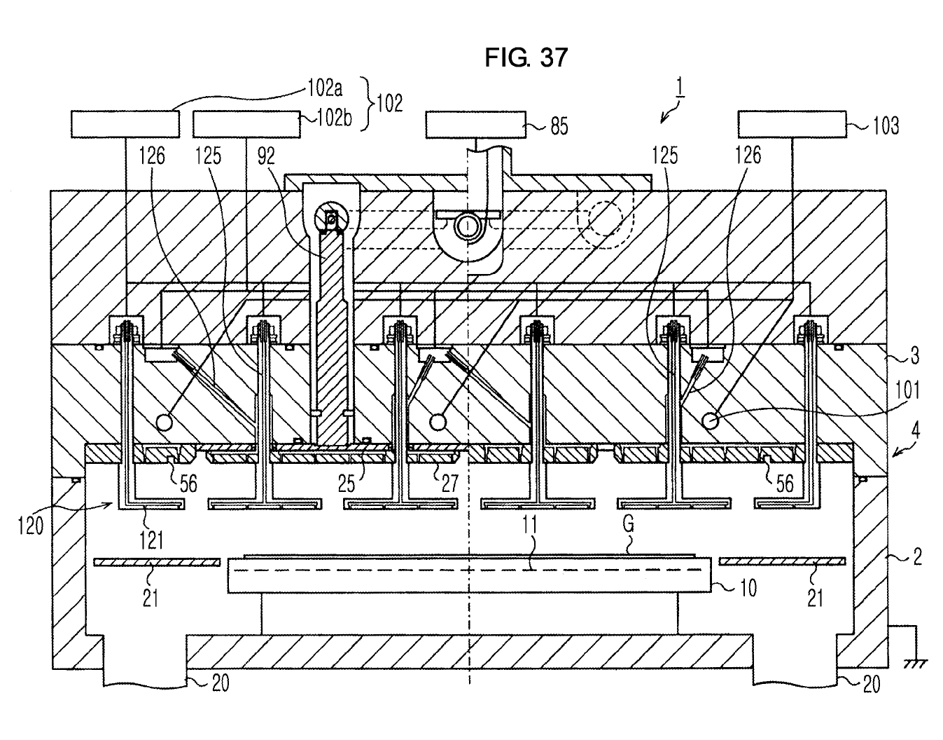

FIG. 37 is a longitudinal-sectional view showing a schematic configuration of the plasma processing apparatus 1 according to Modified Example 5. In the plasma processing apparatus 1 according to Modified Example 5, a lower gas nozzle 120 is provided in addition to the gas discharge holes 42, 52, and 72 formed on the lower surface of the lid 3 (the lower surface of the metal cover 45, the lower surface of the metal electrode 27, and the lower surface of the side cover 55). The lower gas nozzle 120 is provided in a space between the lower surface of the lid 3 (the lower surface of the metal cover 45, the lower surface of the metal electrode 27, and the lower surface of the side cover 55), and the substrate G. A plurality of gas discharge holes 121 are distributed and opened on the lower surface of the lower gas nozzle 120.

In the plasma processing apparatus 1 according to Modified Example 5, the gas supply source 102 includes a first gas supply source 102a, which supplies a predetermined gas (for example, BF₃) for processing used in film forming, etching, or the like, and a second gas supply source 102b, which supplies a predetermined gas (for example Ar) for plasma excitation, such as a rare gas, or the like. The predetermined gas for film forming or etching supplied from the first gas supply source 102a through a first passage 125 is diffused and supplied from each gas discharge hole 121 of the lower surface of the lower gas nozzle 120 toward the inside of the processing container 4 in the lower portion of the inside of the processing container 4. Meanwhile, the predetermined gas for plasma excitation supplied from the second gas supply source 102b through a second passage 126 is dispersed and supplied from each of the gas discharge holes 42, 52, and 72 of the lower surface of the metal cover 45, the lower surface of the metal electrode 27, and the lower surface of the side cover 55 toward the inside of the processing container 4 in the upper portion of the inside of the processing container 4.

As such, according to the plasma processing apparatus 1 of Modified Example 5, excessive dissociation is suppressed by supplying the gas for processing from the lower portion, where an electron temperature is lowered, and the gas for plasma excitation from the upper portion, thereby performing good plasma process on the substrate G.

While this invention has been particularly shown and described with reference to exemplary embodiments thereof, the present invention is not limited thereto, and it will be understood by those skilled in the art that various changes in form and details may be made therein without departing from the spirit and scope of the invention as defined by the appended claims.

The plasma processing apparatus according to the present invention may form an Al₂O₃ protective film or the like via anodic oxidation of a non-aqueous solution, after performing surface-planarization of electric field complex polishing or electric field polishing on an inner surface of the processing container 4. However, with respect to the plasma processing apparatus performing plasma doping, an MgF₂ protective film is more preferable than the Al₂O₃ protective film since injection is performed by using 100% fluorine gas, such as AsF₃, PF₃, or BF₃. The MgF₂ protective film may be formed under processing conditions of, for example, AlMg (4.5% to 5%) Zr (0.1%)/ F₂ process (200° C.)/350° C. anneal.

For example, an Ni film or Al film having a thickness of, for example, about 10 μm may be formed as a conductor film on the surface of the dielectric 25, except on a portion exposed inside the processing container 4 and an outer circumferential portion of the recess portion of the dielectric 25. As such, by forming the conductor film on the surface of the dielectric 25, an adverse affect on the O-ring 37 or the like is avoided since the microwave is not propagated with respect to locations aside from portion exposed inside the processing container 4. Forming locations of the conductor film may include at least a part among the recess portion 95 formed in the center of the upper surface of the dielectric 25, a portion adjacent to the connecting member 30, and a contacting surface with the metal electrode 27, in addition to a contacting location with the O-ring 37.

An alumina film, an yttria film, a Teflon (registered trademark) film, or the like may be formed as a protective film on the lower surface of the lid 3 or the inner side of the container body 2. Also, the plasma processing apparatus according to the present invention may process a large glass substrate, a circular silicon wafer, or an polygonal SOI (Silicon On Insulator). Also, in the plasma processing apparatus according to the present invention, all plasma processes, such as a film forming process, a diffusing process, an etching process, an ashing process, etc. can be performed. Also in the above, the microwave of 915 MHz is described as an example of the microwave having a frequency of 2 GHz or lower, but the frequency is not limited thereto. For example, a microwave of 896 MHz or 992 MHz may also be applied. Also, not only the microwave but also an electromagnetic wave may be applied. Also, an alumina film may be formed on surfaces of the lid 3, the container body 2, the metal electrode 27, the metal cover 45, the side cover 55, the connecting members 30, 46, and 65, etc. In the above, an example of discharging the gas from the gas discharge holes 42, 52, and 72 opened on the upper surface of the processing container 4 has been described, but alternatively, the gas may be discharged toward a lower space of the lid 3 from a container side wall. Also, the present application defines a metal body disposed on the lower surface of the dielectric as a “metal electrode”, and the metal electrode 27 of an embodiment is formed to have a metal plate shape and electrically connected to the lid. However, the metal electrode 27 may be a metal film adhered to the lower surface of the dielectric 25, instead of the metal plate, and may float without being electrically connected to the lid.

### INDUSTRIAL APPLICABILITY

The present invention may be used in, for example, a CVD process or an etching process.

1. A plasma processing apparatus comprising a processing container which is formed of metal and receives a substrate to be plasma-processed, an electromagnetic wave source which supplies an electromagnetic wave required to excite plasma in the processing container, and a plurality of dielectrics, through which the electromagnetic wave supplied from the electromagnetic wave source transmits to the inside of the processing container and which have a part that is exposed to the inside of the processing container, provided on a lower surface of a lid of the processing container,
wherein a metal electrode is provided on a lower surface of each of the dielectrics, and
wherein a surface wave propagating portion, through which the electromagnetic wave is propagated, is formed on each of two different sides of such part of each dielectric that is exposed between the metal electrode and the lower surface of the lid, and the surface wave propagating portion on said two different sides have the substantially similar shapes as each other or the substantially symmetrical shapes to each other.

2. A plasma processing apparatus comprising a processing container which is formed of metal and receives a substrate to be plasma-processed, an electromagnetic wave source which supplies an electromagnetic wave required to excite plasma in the processing container, and a plurality of dielectrics, through which the electromagnetic wave supplied from the electromagnetic wave source transmits to the inside of the processing container and which have a part that is exposed to the inside of the processing container, provided on a lower surface of a lid of the processing container,
wherein a metal electrode is provided on a lower surface of each of the dielectrics, and
wherein a surface wave propagating portion, through which the electromagnetic wave is propagated, is formed adjacent to at least a portion of such part of each dielectrics that is exposed between the metal electrode and the lower surface of the lid, and said adjacent surface wave propagating portion has a substantially similar shape as a shape of the dielectric or substantially symmetrical shape to the shape of the dielectric.

3. A plasma processing apparatus comprising a processing container which is formed of metal and receives a substrate to be plasma-processed, an electromagnetic wave source which supplies an electromagnetic wave required to excite plasma in the processing container, and a plurality of dielectrics, through which the electromagnetic wave supplied from the electromagnetic wave source transmits to the inside of the processing container and which have a part that is exposed to the inside of the processing container, provided on a lower surface of a lid of the processing container,
wherein a metal electrode is provided on a lower surface of each of the dielectrics, and
such part of each dielectric that is exposed between the metal electrode and the lower surface of the lid has a substantially polygonal outline when viewed from the inside of the processing container, and
wherein the plurality of dielectrics are disposed with vertical angles of the polygonal outlines being adjacent to each other, and
a surface wave propagating portion, through which the electromagnetic wave is propagated, is formed on the lower surface of the lid exposed in the processing container and a lower surface of the metal electrode.

4. The plasma processing apparatus of claim 1, wherein the dielectrics have substantially tetragonal plate shapes;

5. The plasma processing apparatus of claim 4, wherein the tetragon is a square, a rhomb, a square having round corners, or a rhomb having round corners.

6. The plasma processing apparatus of claim 1, wherein the dielectrics have substantially triangular plate shapes.

7. The plasma processing apparatus of claim 6, wherein the triangle is an equilateral triangle, or an equilateral triangle having round corners.

8. The plasma processing apparatus of claim 1, wherein a shape of the lower surface of the lid, which is surrounded by the plurality of dielectrics and exposed inside the processing container, and a shape of a lower surface of the metal electrode are substantially identical, when viewed from the inside of the processing container.

9. The plasma processing apparatus of claim 1, wherein an outer edge of each dielectric is on an outer side than an outer edge of the metal electrode, when viewed from the inside of the processing container.

10. The plasma processing apparatus of claim 1, wherein an outer edge of each dielectric is on a same line as or on an inner side than an outer edge of the metal electrode, when viewed from the inside of the processing container.

11. The plasma processing apparatus of claim 1, wherein a thickness of each dielectric is equal to or less than 1/29 of a distance between centers of the neighboring dielectrics.

12. The plasma processing apparatus of claim 1, wherein a thickness of each dielectric is equal to or less than 1/40 of a distance between centers of the neighboring dielectrics.

13. The plasma processing apparatus of claim 1, wherein the dielectrics are inserted into a recess portion formed on the lower surface of the lid.

14. The plasma processing apparatus of claim 13, wherein the lower surface of the lid exposed inside the processing container and a lower surface of the metal electrode are disposed on a same plane.

15. The plasma processing apparatus of claim 13, wherein the lower surface of the lid exposed inside the processing container and a lower surface of the metal electrode are covered by a passivation protective film.

16. The plasma processing apparatus of claim 1, wherein an average roughness about the center line in the lower surface of the lid exposed inside the processing container and a lower surface of the metal electrode is 2.4 μm or less.

17. The plasma processing apparatus of claim 1, wherein an average roughness about the center line in the lower surface of the lid exposed inside the processing container and a lower surface of the metal electrode is 0.6 μm or less.

18. The plasma processing apparatus of claim 1, wherein a metal cover electrically connected to the lid is attached to a region adjacent to each dielectric, in the lower surface of the lid, and
a surface wave propagating portion, through which an electromagnetic wave is propagated, is formed on a lower surface of the metal cover exposed inside the processing container.

19. The plasma processing apparatus of claim 18, wherein a side surface of the dielectric is adjacent to a side surface of the metal cover.

20. The plasma processing apparatus of claim 18, wherein the lower surface of the metal cover exposed inside the processing container and the lower surface of the metal electrode are disposed on a same plane.

21. The plasma processing apparatus of claim 18, wherein a shape of the lower surface of the metal cover and a shape of the lower surface of the metal electrode are substantially same, when viewed from the inside of the processing container.

22. The plasma processing apparatus of claim 18, wherein an average roughness about the center line in the lower surface of the metal cover exposed inside the processing container and the lower surface of the metal electrode is 2.4 μm or less.

23. The plasma processing apparatus of claim 18, wherein average roughness about the center line in the lower surface of the metal cover exposed inside the processing container and the lower surface of the metal electrode is 0.6 μm or less.

24. The plasma processing apparatus of claim 1, comprising a plurality of connecting members, which penetrate through holes formed on the dielectrics, and fix the metal electrode to the lid.

25. The plasma processing apparatus of claim 24, wherein an elastic member, which electrically connects the lid and the metal electrode, is disposed on at least a part of the holes formed on the dielectrics.

26. The plasma processing apparatus of claim 24, wherein the connecting members are formed of a metal.

27. The plasma processing apparatus of claim 24, wherein lower surfaces of the connecting members exposed inside the processing container are disposed on a same plane as the lower surface of the metal electrode.

28. The plasma processing apparatus of claim 24, wherein each dielectric has a substantially tetragonal plate shape, and the connecting members are disposed on a diagonal of the tetragon.

29. The plasma processing apparatus of claim 28, wherein four connecting members are disposed per one dielectric.

30. The plasma processing apparatus of claim 1, comprising an elastic member, which elastically supports the dielectric and the metal electrode toward the lid.

31. The plasma processing apparatus of claim 1, wherein a continuous groove is formed on the lower surface of the lid, and the surface wave propagating portion and the plurality of dielectrics are disposed inside a region surrounded by the groove.

32. The plasma processing apparatus of claim 31, wherein the surface wave propagating portion is divided by the groove.

33. The plasma processing apparatus of claim 1, wherein a continuous convex portion is formed on an inner side of the processing container, and the surface wave propagating portion and the plurality of dielectrics are disposed in a region surrounded by the convex portion.

34. The plasma processing apparatus of claim 33, wherein the surface wave propagating portion is divided by the convex portion.

35. The plasma processing apparatus of claim 1, comprising one or more metal rods which are on upper portions of the dielectrics, do not penetrate through the dielectrics, have lower ends adjacent to or close to upper surfaces of the dielectrics, and transmit an electromagnetic wave to the dielectrics.

36. The plasma processing apparatus of claim 35, wherein the metal rods are disposed on center portions of the dielectrics.

37. The plasma processing apparatus of claim 35, comprising a sealing member, which divides an atmosphere inside the processing container from an atmosphere outside the processing container, between the dielectrics and the lid.

38. The plasma processing apparatus of claim 1, wherein an area of exposed parts of the dielectrics is equal to or less than ½ of an area of the surface wave propagating portion.

39. The plasma processing apparatus of claim 1, wherein an area of exposed parts of the dielectrics is equal to or less than ⅕ of an area of the surface wave propagating portion.

40. The plasma processing apparatus of claim 1, comprising a gas discharging unit which is on the surface wave propagating portion and discharges a predetermined gas to the processing container.

41. The plasma processing apparatus of claim 1, wherein an area of exposed parts of the dielectrics is equal to or less than ⅕ of an area of an upper surface of the substrate.

42. The plasma processing apparatus of claim 1, wherein a frequency of an electromagnetic wave supplied from the electromagnetic wave source is equal to or less than 2 GHz.
